(19) United States
(12) Patent Application Publication
(10) Pub. No.: US 2023/0119833 A1
(43) Pub. Date: Apr. 20, 2023

(54) NMR METHODS FOR CHARACTERIZING IRON SUCROSE

(71) Applicant: Amphastar Pharmaceuticals, Inc., Rancho Cucamonga, CA (US)

(72) Inventors: Jack Yongfeng ZHANG, Diamond Bar, CA (US); Mary Zi-Ping LUO, Diamond Bar, CA (US); Jie Fei DING, Riverside, CA (US); Justin Jun WEI, Rancho Cucamonga, CA (US); Richard BAO, Rancho Cucamonga, CA (US)

(21) Appl. No.: 17/921,239

(22) PCT Filed: May 4, 2021
(86) PCT No.: PCT/US2021/030670

§ 371 Date: Oct. 25, 2022

Related U.S. Application Data
(60) Provisional application No. 63/019,867, filed on May 4, 2020.

(51) Int. Cl. G01N 24/08; G01R 33/44

(52) U.S. Cl. CPC G01N 24/08; G01R 33/448

(57) ABSTRACT

The present disclosure provides NMR relaxation methods for characterizing iron carbohydrate drug products. The methods measure ¹³C and ¹H nuclei relaxation parameters such as T1 and PWHH include performing 2D T1 NMR, 1D ¹³C NMR and ¹H NMR to characterize certain physiochemical properties of iron sucrose drug products, for purposes of assessing bioequivalence between a tested iron sucrose product and a comparator product. The disclosure further provides a novel Fe(III)/Fe(II) reduction method using a new reducing agent Na₂S₂O₅ and an ¹H NMR method to monitor the Fe(III)/Fe(II) reduction process.

### CROSS-REFERENCE TO RELATED APPLICATIONS

This application claims priority to U.S. Provisional Patent Application No. 63/019,867 (filed May 4, 2020), which is incorporated by reference in its entirety.

### TECHNICAL FIELD

The present disclosure generally pertains to methods for characterizing iron core size in iron carbohydrate complexes, such as e.g. iron sucrose, including iron sucrose drug products, via nuclear magnetic resonance (NMR).

### BACKGROUND

Iron sucrose is clinically indicated for the treatment of iron deficiency anemia, such as iron deficiency anemia in patients with chronic kidney disease (CKD). Currently available iron sucrose drug products include injectable solutions for intravenous administration. Iron sucrose exhibits a colloidal system in the lower nanometer size range in which an iron core (e.g. ferric hydroxide) is surrounded by a carbohydrate shell (e.g. sucrose shell). The iron core can be made of iron salt or iron oxyhydroxide nanoparticles. The carbohydrate shell serves to reduce the release of the bioactive iron and maintain the resulting particle in the colloidal system.

An iron sucrose injectable solution (e.g. single-use vials) is an example of an iron sucrose drug product currently available to patients. An iron sucrose injectable solution is a sterile, colloidal solution of polynuclear iron (III)-hydroxide (e.g. ferric hydroxide) in complex with sucrose. In iron sucrose, sucrose plays the role of ligands in the core of the iron-(III) hydroxide. Iron sucrose injection has a molecular weight of about 34,000 to 60,000 Daltons and a molecular formula of:

[Na₂Fe₅O₈(OH).3(H₂O)]ₙ.m(C₁₂H₂₂O₁₁)

where n is the degree of iron polymerization and m is the number of sucrose particles associated with the iron-(III) hydroxide. For example, there can be as many as 50 (or more) sucrose particles associated with a single iron-(III) hydroxide. Venofer® is an example of a comparator product for iron sucrose, and it is an injectable solution having an equivalent concentration of 20 mg/m of iron.

Following intravenous administration, the iron sucrose drug product dissociates into iron and sucrose. After the dissociation, the iron is transported as a complex with transferrin to target cells such as erythroid precursor cells. The iron in the precursor cells is incorporated into hemoglobin as the cells mature into red blood cells.

In the pharmaceutical industry, depending on the approval pathway sought, regulatory agencies may require a proposed (tested) drug product to be bioequivalent to an existing approved drug product. To prove bioequivalence, physiochemical properties between the tested proposed drug product and approved drug product can be characterized and analyzed. However, different drug products have different physiochemical properties, which may require developing new characterization methods, particularly with complex drug products such as iron sucrose. In this regard, is a technical challenge to characterize iron sucrose drug products because of its unique colloidal system and nanometer size range. For example, the characterization of the sucrose shell, such as its surface properties and composition, are important physiochemical properties to characterize for assessing bioequivalence. In addition to iron sucrose, other known iron carbohydrate complex drug products include high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®). These iron carbohydrate complexes have the same (or similar) iron core but they differ in the type and size of carbohydrate moiety surrounding the iron core, which results in significantly different pharmacokinetic and pharmacological properties. For example, high molecular weight iron dextran has a higher incidence of anaphylaxis and anaphylactoid reactions compared to iron sucrose and sodium ferric gluconate. In addition, differences in the carbohydrate surface properties may affect iron release rate and clearance rate after injection. Therefore, needed is a robust method to accurately characterize the carbohydrate shell composition and surface properties.

NMR nucleus relaxation is a critical NMR process by which nuclei return to equilibrium magnetic state from excited magnetic state. Nucleus NMR relaxation rate provides molecular structure information because it is related to structure parameters such as molecular size, molecular weight, number, and distance of neighboring nuclei. Paramagnet Fe (III) has very strong effect on ¹³C and ¹H nuclei relaxation in iron sucrose because the Fe (III) has five unpaired electrons and each unpaired electron causes a strong electronic magnetic moment. The absolute value of the magnetic moment associated with the electron is 658 times higher than magnetic moment of a proton nucleus. Because of Fe (III)'s strong electronic magnetic moment, Fe (III) status such as Fe (III) core size and size distribution, Fe (III) core structure and morphology, amount of free Fe (III) ions in iron sucrose solution could affect ¹³C and ¹H nucleus relaxation rate. Therefore, this present patent use ¹³C and ¹H nucleus relaxation rate as smart probes to monitor iron sucrose product quality and characterize iron sucrose.

Further described herein are the two principal types of relaxations: spin-lattice relaxation and spin-spin relaxation which are described by two relaxation time constants T1 and T2, respectively. Different structures of iron sucrose give different ¹³C and ¹H relaxation rates which results in different T1 and T2 values. Since PWHH is inversely proportional to T2, this patent measures PWHH to describe spin-spin relaxation rate information of iron sucrose. This disclosure also measures T1 value to get spin-lattice relaxation rate information of iron sucrose.

Accordingly, embodiments of the present disclosure address these technical challenges by introducing methods to characterize iron carbohydrate complexes, such as iron sucrose, using novel ¹³C and ¹H NMR methods. These disclosed methods also include a novel Fe(III)/Fe(II) kinetic reduction method using combination of a new reducing agent Na₂S₂O₅ and 1H NMR. This disclosure improves upon alternative techniques (e.g., using UV/Vis and ascorbic acid) by replacing using a novel NMR method, replace ascorbic acid with Na₂S₂O₅. The present disclosure's novel NMR and Na₂S₂O₅ combination reduction method improves upon known methods to reduce iron sucrose which may help to control and monitor the batch to batch bioequivalence of iron carbohydrate complexes, including iron sucrose.

### SUMMARY

Exemplary embodiments of the present disclosure address at least the above problems and/or disadvantages and advance the art by providing at least the features described below. Additional objects, advantages, and salient features of exemplary embodiments of the present disclosure will become apparent to those skilled in the art from the following detailed description, which, taken in conjunction with the annexed drawings, discloses exemplary embodiments of the present invention.

The disclosure provides for various methods of characterizing iron carbohydrate drug products, including but not limited to an iron sucrose drug product, a high molecule weight iron dextran drug product, a low molecular weight iron dextran drug product, a sodium ferric gluconate drug product, an iron carboxymaltose drug product, or a ferumoxytol drug product, using NMR. By comparing the NMR results for an iron carbohydrate drug product to the comparator product for the iron carbohydrate, it is possible to determine if there is bioequivalence.

Accordingly, one embodiment of the invention is method for characterizing iron carbohydrate comprising the steps of:

performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product;

performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate;

determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak;

determining a second set of PWHH having at least twelve PWHHs, wherein each PWHH corresponds to a ¹³C peak on the second ¹³C NMR spectrum; and

analyzing the first and second sets of PWHHs by comparing the first set of PWHH to the second set of PWHH, wherein when the results of the analysis of the first and second sets of PWHHs are the same or substantially the same the tested iron carbohydrate drug product and the comparator product for iron carbohydrate are structurally equivalent.

Another embodiment of the invention is a method for characterizing iron carbohydrate comprising the steps of:

performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product;

performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate;

performing ¹³C NMR on a third sample to produce a third ¹³C NMR spectrum, wherein the third sample comprises a plurality of carbohydrate particles, and the third sample does not include any iron particle;

determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak;

determining a second set of PWHH having at least twelve PWHHs, wherein each PWHH corresponds to a ¹³C peak on the second ¹³C NMR spectrum;

determining a third set of PWHH having at least twelve PWHHs, wherein each PWHH corresponds to a ¹³C peak on the third ¹³C NMR spectrum;

determining a first set of relative PWHH (“RPWHH”) having at least n RPWHHs, wherein each RPWHH is the respective PWHH from the first set of PWHH divided by the corresponding PWHH from the third set of PWHH;

determining a second set of RPWHH having at least twelve RPWHHs, wherein each RPWHH is the respective PWHH from the second set of PWHH divided by the corresponding PWHH from the third set of PWHH; and

analyzing the first and second sets of RPWHHs by comparing the first set of RPWHH to the second set of RPWHH, wherein when the results of the analysis of the first and second sets of RPWHHs are the same or substantially the same the tested iron carbohydrate drug product and the comparator product for the iron carbohydrate are structurally equivalent.

An alternate embodiment of the invention is a method for characterizing iron carbohydrate comprising the steps of:

performing ¹³C NMR on a first set of samples to produce a corresponding first set of ¹³C NMR spectra, wherein the first set of samples comprises at least three (3) different concentrations of iron in a first sample, wherein the first sample comprises a plurality of iron carbohydrate particles having an iron core particle and a plurality of carbohydrate particles surrounding the iron core particle, and wherein the first sample is a tested iron carbohydrate drug product;

performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron carbohydrate particles having an iron core particle a plurality of carbohydrate particles surrounding the iron core particle, and wherein the second sample is a comparator product for the iron carbohydrate;

performing ¹³C NMR on a third sample to produce a third ¹³C NMR spectrum, wherein the third sample comprises a plurality of carbohydrate particles, and the third sample does not include any iron particle;

determining, for each concentration of the first sample, an average value of a first set of peak width at half-height (PWHH), wherein the PWHH is a width at a half-height of the ¹³C peak, wherein the first set of PWHH comprises at least n PWHHs, wherein n is the number of carbon atoms in the iron carbohydrate, each PWHH corresponding to each ¹³C peak in the respective ¹³C NMR spectrum of the first set of the ¹³C NMR spectra, and wherein the average value is the mean of the at least n PWHHs;

determining, for each concentration of the second sample, the average value of a second set of PWHH, wherein the second set of PWHH comprises at least twelve PWHHs, each PWHH corresponding to each ¹³C peak in the respective ¹³C NMR spectrum of the second set of the ¹³C NMR spectra;

determining the average value of a third set of PWHH, wherein the third set of PWHH comprises at least twelve PWHHs, each PWHH corresponding to each ¹³C peak in the third ¹³C NMR spectrum;

determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH;

determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH; and

comparing the first set of RPWHH to the second set of RPWHH, wherein when the first and second sets of RPWHHs are the same or substantially the same the tested iron carbohydrate drug product and the comparator product for the iron carbohydrate are structurally equivalent.

Yet another embodiment of the invention is a method for characterizing iron carbohydrate comprising the steps of:

applying a reducing agent to one or more first samples, wherein the first sample comprises a plurality of iron carbohydrate particles having an iron core particle and a plurality of carbohydrate particles surrounding the iron core particle, wherein the first sample is a tested iron carbohydrate drug product, and wherein the reducing agent reduces the iron core particle from iron (III) to iron (II);

performing ¹H NMR to at least one ¹H in the first sample for an NMR analysis time period, wherein the at least one ¹H is an ¹H associated with the carbohydrate particle, and during the NMR analysis time period, the reducing agent is reducing iron(III) to iron(II) of the iron core particle of the first sample;

applying the reducing agent to one or more second samples, wherein the second sample comprises a plurality of iron carbohydrate particles having an iron core particle and a plurality of carbohydrate particles surrounding the iron core particle, wherein the second sample is a comparator product for the iron carbohydrate, wherein the reducing agent reduces the iron core particle from iron (III) to iron (II);

performing ¹H NMR to at least one ¹H on the second sample for the NMR analysis time period, wherein the at least one ¹H is the same ¹H associated with the carbohydrate particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples, wherein the tested iron carbohydrate drug product and the comparator product for iron carbohydrate are structural equivalents when the change in the intensity is the same or substantially the same.

Another alternate embodiment of the invention is a method for characterizing iron carbohydrate comprising the steps of:

performing T1 NMR and determining a T1 value on a first sample, wherein the first sample comprises a plurality of iron carbohydrate particles having an iron core particle and a plurality of carbohydrate particles surrounding the iron core particle, wherein the first sample is a tested iron carbohydrate drug product;

performing T1 NMR and determining a T1 value on a second sample, wherein the second sample comprises a plurality of iron carbohydrate particles having an iron core particle and a plurality of carbohydrate particles surrounding the iron core particle, wherein the second sample is a comparator product for the iron carbohydrate; and

analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

Another embodiment of the invention is a method for characterizing iron carbohydrate comprising the steps of:

performing 2D T1 and determining T1 value on a first sample, wherein the first sample comprises a plurality of iron sucrose particles having an iron core particle and a plurality of sucrose particles surrounding the iron core particle, wherein the first sample is a tested iron carbohydrate drug product;

performing 2D T1 NMR and determine T1 value on a second sample, wherein the second sample comprises a plurality of iron sucrose particles having an iron core particle and a plurality of sucrose particles surrounding the iron core particle, wherein the second sample is a comparator product for the iron carbohydrate; and

analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

### BRIEF DESCRIPTION OF THE FIGURES

The above and other exemplary features and advantages of certain exemplary embodiments of the present disclosure will become more apparent from the following description of certain exemplary embodiments thereof when taken in conjunction with the accompanying drawings in which:

FIG. 1 depicts the structure of a sucrose particle and the numbering of the 12 carbon atoms in the sucrose particle.

FIG. 2 is a graph illustrating a peak width at half-height (PWHH) of a ¹³C Peak.

FIG. 3 is a graph showing ¹³C NMR spectra of sucrose in iron sucrose drug products.

FIG. 4 is a graph illustrating the relative averaged PWHH of ¹³C Peaks versus iron (Fe(III)) concentration (mg/mL) in iron sucrose.

FIG. 5 shows a ¹H NMR spectrum of the H atoms in a sucrose particle.

FIG. 6 is a graph illustrating reduction kinetic curves based on the Log percentage of the ¹H peak intensity change versus time (minutes) for the comparator product and tested iron sucrose drug products.

FIG. 7 is a graph illustrating the T1 NMR of a sample of Venofer®. FIG. 7 show that T1 value is determined by fitting the magnetization curve using equation as below:

M=M₀(1−2e^{-t/T1})

FIG. 8 is a graph comparing the ¹H NMR spectra for a comparator product (Venofer 9043) and a tested product (bad iron sucrose Lot 04-17-14 (negative control)).

FIG. 9 is a graph comparing the ¹H NMR spectra for a comparator product (Venofer 9043) and a tested product (good iron sucrose Lot 09-20-19-B).

FIG. 10 is a graph comparing the ¹H NMR spectra for a comparator product (Venofer 9043) and a tested product (Lot 01-27-18-B).

Throughout the drawings, like reference numerals will be understood to refer to like elements, features, and structures.

### DETAILED DESCRIPTION

The matters exemplified in this description are provided to assist in a comprehensive understanding of exemplary embodiments of the disclosure with reference to the accompanying drawing figures. While the subject matter of the present disclosure has been described in connection with certain embodiments, it is to be understood that the disclosure is not limited to the disclosed embodiments, but, on the contrary, is intended to cover various modifications and equivalent arrangements included within the spirit and scope of the appended claims, and equivalents thereof. Accordingly, those of ordinary skill in the art will recognize that various changes and modifications of the exemplary embodiments described herein can be made without departing from the scope and spirit of the present disclosure.

The disclosure is based on the discovery that it is possible to demonstrate structural equivalence between an iron carbohydrate drug product, such as a sucrose drug product, and an existing comparator product by demonstrating identical physiochemical properties, i.e. the sameness of these properties, as assessed by NMR using the unique methods disclosed herein. Based on a demonstration of structural equivalence, it is then possible to proceed to assess if the compounds are structurally equivalent.

The disclosure is based on quantitative studies of the NMR relaxation rate of iron carbohydrates, such as iron sucrose, using relaxation parameters T1 and T2 related PWHH. NMR relaxation is a critical NMR process by which nuclei magnetization turns back to the equilibrium state from its excited state after an excited radiofrequency pulse. NMR relaxation rate is an important because it influences both NMR resolution and sensitivity. Relaxation rates of nuclei can also be related to aspects of molecular structure and behavior in favorable circumstances, in particular internal molecular motions. There are two type of relaxation: spin-lattice relaxation and spin-spin relaxation which are described by two different time constants, T1 and T2, respectively. Since PWHH is inversely proportional to T2 and PWHH is easier to measure, PWHH was studied to obtain spin-spin relaxation rate information for iron sucrose. This disclosure also provides methods to measure the T1 value to obtain spin-lattice relaxation information for iron carbohydrates, such as e.g. iron sucrose.

Via use of the methods of the invention, it is possible to demonstrate structural equivalence and possible functional equivalence of an iron carbohydrate product without having to rely on time consuming and costly in vivo studies. The methods of the invention also allow for the establishment of bioequivalence by only requiring one test protocol to establish bioequivalence.

The methods of the claimed invention also allow for identifying putative iron carbohydrate drug product that have bioequivalence to an existing comparator product by demonstrating identical physiochemical properties as assessed by NMR.

The present disclosure provides methods for characterizing iron carbohydrate complexes, such as iron sucrose drug products, via NMR. Disclosed methods include performing ¹³C NMR and ¹H NMR to characterize certain physiochemical properties of iron carbohydrate drug products, such as iron sucrose drug products, to assess bioequivalence between a tested iron carbohydrate drug product, such as a tested iron sucrose product, and a comparator product. The disclosed methods further enable the correlation of the iron core concentration based on certain physiochemical properties of the carbohydrate particles in an iron carbohydrate, such as sucrose particles in iron sucrose.

### I. Definitions

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage, or mode of operation.

Unless otherwise defined herein, scientific, and technical terms used in connection with embodiments of present disclosure shall have the meanings that are commonly understood by those of ordinary skill in the art. Nomenclatures used in connection with, and techniques described herein are those known and commonly used in the art. Also, descriptions of well-known functions and constructions are omitted for clarity and conciseness.

Throughout the text and claims, the terms “about” and “substantially” are used as terms of approximation, not terms of degree, and reflect the inherent variation associated with measurement, significant figures, and interchangeability, all as understood by a person having ordinary skill in the relevant art. Also, it is to be understood that throughout this disclosure and the accompanying claims, even values that are not preceded by the term “about” are also implicitly modified by that term, unless otherwise specified.

As used herein, the singular forms “a,” “an,” and “the” are intended to include the plural forms as well, unless the context clearly indicates otherwise. It will be further understood that the terms “comprises,” “comprising,” “includes,” “including,” “have” and/or “having” when used herein, specify the presence of stated features, integers, steps, operations, elements, and/or components, but do not preclude the presence or addition of one or more other features, integers, steps, operations, elements, components, and/or groups thereof.

As used herein, the term “tested product” refers an iron carbohydrate drug product that is tested using the methods of the disclosure. The tested product may be a product that has bioequivalence to a comparator product.

As used herein, the term “comparator product” or “CP” refers to an iron carbohydrate drug product to which the tested product is compared. The comparator product may an iron carbohydrate drug product, which has received regulatory approval by, for example, the FDA, e.g. an approved drug. In certain embodiments, the comparator product may be Venofer®, Dexferrum®, Cosmofer®, Ferrlecit®, Ferinject®, Injectafer®, or Feraheme®.

As used herein, the term “EEC” refers to equivalence evaluation criteria. The EEC can be determined using one or more of the following EEC Equations discussed below.

As used herein, the term “PWHH” refers to peak width at half-height. As discussed below the relative PWHH may be based on the ¹³C peaks of the carbohydrate, for example the ¹³C peaks of sucrose.

As used herein, the term relative “RWPHH” refers to relative PWHHs.

### II. Iron Carbohydrate Complexes

The present disclosure discloses methods for characterizing iron carbohydrate complexes, such as iron sucrose drug products. Currently available iron sucrose drug products include iron sucrose injectable solutions, such as injectable solutions in single-use vials.

A. Iron Sucrose Drug Products

An iron sucrose injectable solution is a sterile, colloidal solution of polynuclear iron (III)-hydroxide (e.g. ferric hydroxide) in complex with sucrose. Iron sucrose injection has a molecular weight of about 34,000 to 60,000 Daltons and a molecular formula of:

[Na₂Fe₅O₈(OH).3(H₂O)]ₙ.m(C₁₂H₂₂O₁₁)

where n is the degree of iron polymerization and m is the number of sucrose particles associated with the iron (III)-hydroxide. In iron sucrose, sucrose plays the role of ligands in the core of iron hydroxide.

Therefore, in an exemplary embodiment, the iron sucrose includes one or more iron sucrose particles, and the iron sucrose particle has an iron particle in its core and one or more sucrose particles exterior to the iron particle in its core. Because the iron is located substantially at the core of its respective iron sucrose particle, the iron particle can also be referred to as the iron core particle. Fe(III) or iron (III)-hydroxide can be the iron in the iron core particle. Also, the iron core particle generally has a particle diameter in a range of about 2 nm to about 5 nm, and therefore, the iron core particle can also be referred to as an iron core nanoparticle.

Similarly, the iron sucrose particle can also be referred to as an iron sucrose nanoparticle because it generally has a particle diameter in a range of about 8 nm to about 10 nm. Likewise, in iron sucrose, the sucrose particle is generally in the nanometer range, and thus, the sucrose particle can also be referred to as a sucrose nanoparticle.

In iron sucrose, the sucrose particle acts as a ligand to the iron core particle. Thus, in some embodiments, a plurality of sucrose particles surrounds the iron core particle. In some embodiments, a plurality of sucrose particles surrounds the iron core particle by forming a shell of sucrose particles around the iron core particle. In some embodiments, the plurality of sucrose particles can be as many as 50 sucrose particles surrounding the iron core particle.

In another exemplary embodiment, the iron sucrose is an iron sucrose drug product. In some embodiments, the iron sucrose drug product is an iron sucrose injectable solution, including an injectable solution in a single-use vial.

In an exemplary embodiment, the iron sucrose drug product has iron, such as Fe(III) or iron (III) hydroxide, present at a concentration, or an equivalent concentration, of about 20 mg/mL. In some embodiments, the iron sucrose drug product has iron present at a concentration, or an equivalent concentration, of about 20 mg/mL including but is not limited to, about 50 mg/2.5 mL, about 100 mg/5 mL, about 200 mg/10 mL, about 65 mg/3.25 mL, or about 75 mg/3.75 mL. Thus, in some embodiments, a single-use vial iron sucrose drug product contains about 2.5 mL, about 3.25 mL, about 3.75 mL, about 5 mL, or about 10 mL of the iron sucrose injectable drug product.

In some embodiments, the iron sucrose drug product includes approximately 30% sucrose w/v (weight to volume) and has a pH of approximately 10.5 to 11.1. In some embodiments, the iron sucrose drug product is a comparator product, such as Venofer® having iron present at a concentration, or equivalent concentration, of about 20 mg/mL. In other embodiments, the iron sucrose drug product is a tested drug product, such as a tested drug product having iron present at a concentration, or equivalent concentration, of about 20 mg/mL.

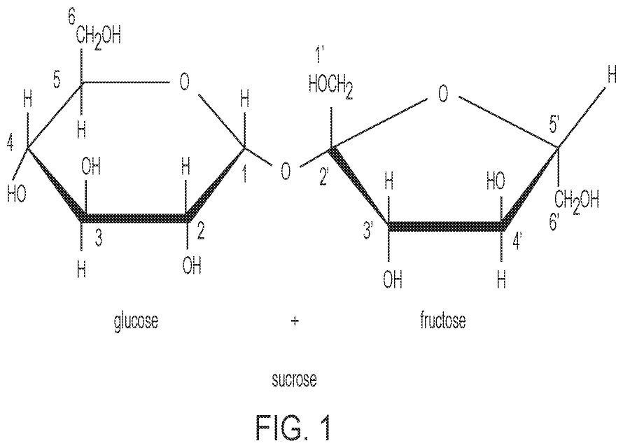

The sucrose particle is a disaccharide composed of the monosaccharides glucose and fructose, as shown in FIG. 1. Sucrose has the molecular formula C₁₂H₂₂O₁₁ and its molecular mass is about 342.3 Daltons. FIG. 1 depicts the structure of a sucrose particle and the numbering of the 12 carbon (C) atoms in a sucrose particle. The terms “sucrose” and “sucrose particle” each have the same meaning and are thus used synonymously and interchangeably herein.

In a sucrose particle, there are 22 hydrogen (H) atoms which can be classified as into three categories. The first category covers the eight (8) H atoms that are in the eight (8) hydroxyl groups of sucrose. The second category covers the fourteen (14) H atoms bonded to 11 carbon (C) atoms. These 11 C atoms are the C atoms numbered 1, 2, 3, 4, 5, 6, 1′, 2′, 3′, 4′, 5′, and 6′ in FIG. 1. The third category covers the only C atom that has no bonded H atom, which is the C atom numbered 2′ in FIG. 1. The disclosed methods using ¹³C NMR and ¹H NMR can characterize these C atoms and H atoms, respectively, of the sucrose particle.

B. Other Iron Carbohydrate Drug Products

The subject matter of the present disclosure and the disclosed methods may also be applicable to other iron carbohydrate complexes, including, but not limited to, iron carbohydrate complex drug products such as high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®).

Accordingly, in some embodiments, the methods characterizes other iron carbohydrate complexes, such as a high molecule weight iron dextran drug product, a low molecular weight iron dextran drug product, a sodium ferric gluconate drug product, an iron carboxymaltose drug product, or a ferumoxytol drug product.

### III. Equivalence Evaluation Criteria (EEC)

For the characterization methods disclosed herein, the equivalence evaluation criteria (EEC) can be determined using one or more of the following EEC Equations:

EEC Lower Limit=Rₘᵢₙ*(1−η) (herein referred to as “EEC Equation 1”) (1)

EEC Upper Limit=Rₘₐₓ*(1+η) (herein referred to as “EEC Equation 2”) (2)
where Rₘᵢₙ and Rₘₐₓ are the minimum and maximum results from the comparator product samples (e.g. lots) for a tested characterization parameter, and
η is the allowable percentage range, which can be determined based on the comparator product's “Extreme Range” (E-range or E_{range}) that is defined as follows:

$${E}_{Range} = \frac{{R}_{Max} - {R}_{Min}}{{R}_{Mean}} \times 100 \% \qquad ( 3 )$$

(herein referred to as “EEC Equation 3”)
η is reasonably assigned as higher of 10% and a half of E_{Range}, namely

$$η = Max ( 10 \% , \frac{1}{2} {E}_{Range} ) \qquad ( 4 )$$

(herein referred to as “EEC Equation 4”)
If E_{Range} is used, η will be round-off to the higher 5%, thus the value of η could be 10%, 15%, or 20% . . . depending on the experimental results of E_{Range} for the tested characterization parameters.

In some embodiments where there are multiple parameters for one characterization method, such as the PWHH and RPWHH methods disclosed herein (which has multiple parameters for the ¹³C NMR spectra for 12 C atoms), then η is based on the maximum E_{Range} for the 12 C atoms, or a minimum of η=20% will be used for all these multiple parameters.

$$η = Max [ 20 \% , \frac{1}{2} Max ( {E}_{Range}^{( 1 )} , {E}_{Range}^{( 2 )} , {E}_{Range}^{( 3 )} , … ) ] \qquad ( 5 )$$

(herein referred to as “EEC Equation 5”)

In some embodiments, the characterization parameters for which the method is very sensitive, such as the ¹³C NMR or ¹H chemical shifts, the EEC can be determined based on the following EEC Equations:

EEC Lower Limit=Rₘᵢₙ−δ (herein referred to as “EEC Equation 6”) (6)

EEC Upper Limit=Rₘₐₓ+δ (herein referred to as “EEC Equation 7”) (7)
where Rₘᵢₙ and Rₘₐₓ are the minimum and maximum results from the comparator product samples (e.g. lots) for a tested characterization parameter, and
where δ is a relatively low value and is proposed per the specific characterization method.

The methods disclosed herein can use one or more of these EEC Equations to determine bioequivalence or sameness between the comparator product drug products and the tested iron sucrose drug products.

### IV. Methods of Characterizing Iron Carbohydrate Complexes Using NMR

Disclosed herein are methods for characterizing iron carbohydrate complex, such as iron sucrose, using nuclear magnetic resonance (NMR), such as ¹³C NMR. ¹³C NMR refers to Carbon-13 nuclear magnetic resonance and can be used to analyze Carbon (C) atoms in a molecule.

In certain embodiments, the disclosure provides methods of characterizing the carbohydrate in an iron carbohydrate complexes, such as e.g. sucrose in iron sucrose, using Peak Width at Half-Height (PWHH) of the ¹³C peaks of the carbohydrate, such as e.g. sucrose. The disclosure also provides methods of characterizing the carbohydrate in iron carbohydrate complexes, such as e.g. sucrose in iron sucrose, using relative PWHH of the ¹³C peaks of the carbohydrate, such as e.g. sucrose. In other embodiments, the disclosure provides methods of characterizing the iron core using RPWHH of the carbohydrate in the iron carbohydrate complex, such as e.g. sucrose in iron sucrose. In yet other embodiments, the disclosure provides methods of characterizing the change of the carbohydrate over time using ¹H NMR of the carbohydrate in the iron carbohydrate complex, such as sucrose in iron sucrose.

Based on characterizing the iron carbohydrate complex in the iron carbohydrate drug product of interest, such as a tested iron sucrose product, and a comparator product, it is possible to compare the physiochemical properties of both. If the physiochemical properties are the same, then the iron carbohydrate product of interest and the comparator product are structurally equivalent. As noted above in certain embodiments, the bioequivalence may be determined using the EEC equations discussed above.

The methods of invention rely on a comparison of the NMR results between the tested iron carbohydrate (e.g. sucrose) drug product and the comparator product for the iron carbohydrate (e.g. sucrose) to assess if there is bioequivalence. In particular, if the NMR result are the same or substantially same (i.e. so identical that the skilled artisan would conclude they are the same), then the tested iron carbohydrate (e.g. sucrose) drug product and the comparator product for the iron carbohydrate (e.g. sucrose) are structurally equivalent.

In certain embodiments, invention provides for method of characterizing iron carbohydrate comprising the steps of:

performing one or more NMR experiments which can measure NMR relaxation values on a first sample to produce a first NMR relaxation spectrum, wherein the first sample comprises a plurality of iron carbohydrate particles having an iron core particle and a plurality of carbohydrate particles surrounding the iron core particle, wherein the first sample is a tested iron carbohydrate drug product;

performing one or more NMR experiments which can measure NMR relaxation values on a second sample to produce a second NMR relaxation spectrum, wherein the second sample comprises a plurality of iron carbohydrate particles having an iron core particle and a plurality of carbohydrate particles surrounding the iron core particle, wherein the second sample is a comparator product for the iron carbohydrate;

determining relaxation values on a first sample of iron carbohydrate wherein the first sample is a tested iron carbohydrate drug product:

determining relaxation values on a second sample of iron carbohydrate wherein the second sample is a comparator product for the iron carbohydrate; and

analyzing relaxation values by comparing the first relaxation values to the second relaxation values, wherein when the results of the analysis of relaxation values are the same or substantially the same the tested iron carbohydrate drug product and the comparator product for iron carbohydrate are bioequivalent. In certain embodiments, the iron carbohydrate may be iron sucrose. The NMR experiments may include any of the NMR experiments described in A.-E. below. In one embodiment, the NMR experiments are T1, T2, ¹H, ¹³C NMR, and combinations thereof. In certain embodiments, where the iron carbohydrate is sucrose, the plurality of sucrose particles serves as a ligand to the iron core particle. In other embodiments, the plurality of sucrose particle is up to about 50 sucrose particles. In alternate embodiments, the plurality of sucrose particles surrounds the iron core particle by forming a shell of sucrose particles around the iron core particle.

A. Characterization of Sucrose in Iron Sucrose Using Peak Width at Half-Height (PWHH) of ¹³C Peaks of Sucrose

In exemplary embodiments, the methods characterize the sucrose in iron sucrose by performing ¹³C NMR on the C atoms in sucrose, which produces a ¹³C NMR spectrum having at least twelve (12) ¹³C Peaks. Each of these 12 ¹³C Peaks on the ¹³C NMR spectrum correspond to a respective C atom of the 12 C atoms in sucrose, and are identified as 1, 2, 3, 4, 5, 6, 1′, 2′, 3′, 4′, 5′, and 6′ in FIG. 1.

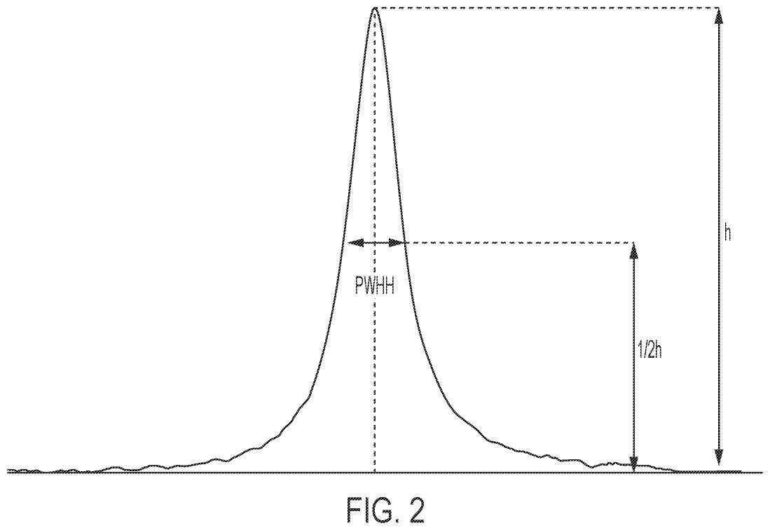

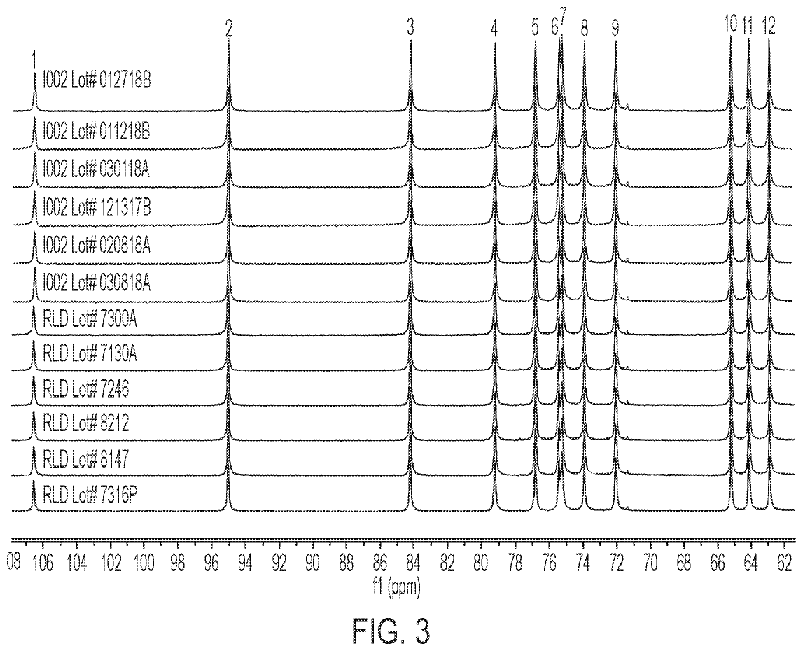

For each of the twelve (12) ¹³C Peaks associated with sucrose, the methods include determining a set of peak width at half-height (PWHH) for each ¹³C Peak on the ¹³C NMR spectrum. The PWHH is a width at a half-height of the ¹³C Peak, as shown in FIG. 2. Thus, the set of PWHH includes at least twelve (12) PWHHs, each PWHH corresponding to each ¹³C Peak associated with the sucrose particle, as shown in FIG. 3. The set of PWHH includes at least one PWHH.

The respective set of PWHHs can be determined for the comparator product and the tested product. The respective set of PWHHs can indicate sameness in terms of physiochemical properties of the sucrose particles for purposes of assessing bioequivalence between comparator product and tested iron sucrose drug products. Indeed, as demonstrated in Example 1 below, the PWHH of each of the twelve (12) ¹³C Peaks for the comparator product can be compared quantitatively to the corresponding PWHH of each of the twelve (12) ¹³C Peaks between the comparator product and tested iron sucrose drug products.

In some embodiments, the methods include determining a set of equivalence evaluation criteria (EEC) based the set of PWHHs for the comparator product. The set of EECs includes at least one EEC. In some embodiments, the EEC can be determined based on one or more of the EEC Equations disclosed herein. In some embodiments, the EEC Equations can be EEC Equations 1, 2, 3, and 5 because PWHH has multiple parameters, one peak for each corresponding ¹³C NMR peak, and thus, a minimum of η=20% can be used across all twelve (12) parameters.

In some embodiments, the methods include determining whether each PWHH in the first set of PWHH meets the respective EEC in the set of EEC. Based on this EEC, the sameness between the two iron sucrose drug products, such as a tested iron sucrose drug product compared to a comparator product, can be evaluated.

Accordingly, in some embodiments, the methods for characterizing iron sucrose comprise the steps of performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; determining a first set of peak width at half-height (PWHH) having at least twelve PWHHs, wherein each PWHH corresponds to a ¹³C Peak on the first ¹³C NMR spectrum, and wherein the PWHH is a width at a half-height of the ¹³C Peak; determining a second set of PWHH having at least twelve PWHHs, wherein each PWHH corresponds to a ¹³C Peak on the second ¹³C NMR spectrum; and analyzing the first and second sets of PWHHs by comparing the first set of PWHH to the second set of PWHH.

In some embodiments, the analyzing step of the method further comprises the steps of determining a set of equivalence evaluation criteria (EEC) based on the second set of PWHH, wherein the first set of EEC comprises at least 12 EECs, wherein each EEC is determined based on EEC Equations 1, 2, 3, and 5, with η=20%, for each PWHH in the second set of PWHH; and determining whether each PWHH in the first set of PWHH meets the respective EEC in the set of EEC.

In some embodiments, the tested iron sucrose drug product and the comparator product both have a concentration, or an equivalent concentration, of about 20 mg/mL of iron sucrose. In some embodiments, the ¹³C Peaks on the first, second, and third ¹³C NMR spectra correspond to the Carbon atoms identified as 1, 2, 3, 4, 5, 6, 1′, 2′, 3′, 4′, 5′, and 6′ in FIG. 1.

The methods of characterizing sucrose in iron sucrose using PWHH of ¹³C peaks of sucrose may be adapted for characterizing other iron carbohydrate complexes such as, e.g. high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®). In exemplary embodiments, the methods characterize the carbohydrate in iron carbohydrate by performing ¹³C NMR on the C atoms in the carbohydrate, which produces a ¹³C NMR spectrum having at least a peak corresponding to the respective C atom of the C atoms in the iron carbohydrate.

For each of the ¹³C Peaks associated with the carbohydrate, the methods include determining a set of peak width at half-height (PWHH) for each ¹³C Peak on the ¹³C NMR spectrum. The PWHH is a width at a half-height of the ¹³C Peak. Thus, the set of PWHH includes at least a PWHH corresponding to each ¹³C Peak associated with the carbohydrate particle. The set of PWHH includes at least one PWHH.

The respective set of PWHHs can be determined for the comparator product and the tested product. The respective set of PWHHs can indicate sameness in terms of physiochemical properties of the carbohydrate particles for purposes of assessing bioequivalence between comparator product and tested iron carbohydrate drug products. Indeed, as demonstrated in Example 1 below, the PWHH of each of the ¹³C Peaks for the comparator product can be compared quantitatively to the corresponding PWHH of each of the ³C Peaks between the comparator product and tested iron carbohydrate drug products.

In some embodiments, the methods include determining a set of equivalence evaluation criteria (EEC) based the set of PWHHs for the comparator product. The set of EECs includes at least one EEC. In some embodiments, the EEC can be determined based on one or more of the EEC Equations disclosed herein. In some embodiments, the EEC Equations can be EEC Equations 1, 2, 3, and 5 because PWHH has multiple parameters, one peak for each corresponding ¹³C NMR peak, and thus, a minimum of η=20% can be used across all parameters (i.e. all carbon peaks of the carbohydrate).

In some embodiments, the methods include determining whether each PWHH in the first set of PWHH meets the respective EEC in the set of EEC. Based on this EEC, the sameness between the two iron carbohydrate drug products, such as a tested iron carbohydrate drug product compared to a comparator product, can be evaluated.

Accordingly, in some embodiments, the methods for characterizing iron carbohydrates comprise the steps of performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product; performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate being tested; determining a first set of peak width at half-height (PWHH) having at least n PWHHs, wherein n is the number of carbon atoms in the iron carbohydrate, wherein each PWHH corresponds to a ¹³C Peak on the first ¹³C NMR spectrum, and wherein the PWHH is a width at a half-height of the ¹³C Peak; determining a second set of PWHH having at least n PWHHs, wherein n is the number of carbon atoms in the iron carbohydrate, wherein each PWHH corresponds to a ¹³C Peak on the second ¹³C NMR spectrum; and analyzing the first and second sets of PWHHs by comparing the first set of PWHH to the second set of PWHH.

In some embodiments, the analyzing step of the method further comprises the steps of determining a set of equivalence evaluation criteria (EEC) based on the second set of PWHH, wherein the first set of EEC comprises at least 12 EECs, wherein each EEC is determined based on EEC Equations 1, 2, 3, and 5, with η=20%, for each PWHH in the second set of PWHH; and determining whether each PWHH in the first set of PWHH meets the respective EEC in the set of EEC.

In some embodiments, the tested iron carbohydrate drug product and the comparator product both have a concentration, or an equivalent concentration, of about 20 mg/mL of the iron carbohydrate.

B. Characterization of Sucrose in Iron Sucrose Using Relative PWHH of ¹³C Peaks of Sucrose.

Another characterization method uses relative PWHHs (“RWPHH”), which can indicate sameness in terms of physiochemical properties of the sucrose particles for purposes of assessing bioequivalence between comparator product and tested iron sucrose drug products. As demonstrated in Examples 1 and 2 below, the RPWHH of each of the 12 ¹³C Peaks for the comparator product can be compared quantitatively to the corresponding RPWHH of each of the 12 ¹³C Peaks between the comparator product and tested iron sucrose drug products.

The RPWHH of each of the twelve ¹³C Peak can be determined. The RPWHH is defined as wⱼ/wₒ, where wₒ is the PWHH for free sucrose (sucrose only, no iron), and wⱼ is the PWHH for the respective iron sucrose drug products, such as the comparator product and the tested product.

In some embodiments for evaluating RPWHH, the EEC can be determined based on the EEC Equations disclosed herein. In some embodiments, the EEC Equations can be EEC Equations 1, 2, 3, and 5 because RPWHH has multiple parameters, one peak for each corresponding ¹³C NMR peak, and thus, a minimum of η=20% can be used across all twelve (12) parameters.

Accordingly, in exemplary embodiments, the methods for characterizing iron sucrose comprise performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; and performing ¹³C NMR on a third sample to produce a third ¹³C NMR spectrum, wherein the third sample comprises a plurality of sucrose particles, and the third sample does not include any iron particle.

In some embodiments, after ¹³C NMR are performed on the three samples, the methods further comprise determining a first set of peak width at half-height (PWHH) having at least twelve PWHHs, wherein each PWHH corresponds to a ¹³C Peak on the first ¹³C NMR spectrum, and wherein the PWHH is a width at a half-height of the ¹³C Peak; determining a second set of PWHH having at least twelve PWHHs, wherein each PWHH corresponds to a ¹³C Peak on the second ¹³C NMR spectrum; and determining a third set of PWHH having at least twelve PWHHs, wherein each PWHH corresponds to a ¹³C Peak on the third ¹³C NMR spectrum.

In some embodiments, after the three sets of PWHHs are determined for the three samples, the methods further comprise determining a first set of relative PWHH (“RPWHH”) having at least twelve RPWHHs, wherein each RPWHH is the respective PWHH from the first set of PWHH divided by the corresponding PWHH from the third set of PWHH; determining a second set of RPWHH having at least twelve RPWHHs, wherein each RPWHH is the respective PWHH from the second set of PWHH divided by the corresponding PWHH from the third set of PWHH; and analyzing the first and second sets of RPWHHs by comparing the first set of RPWHH to the second set of RPWHH. In other embodiments, the set of RPWHHs includes at least one RPWHH.

In some embodiments, the analyzing step of the methods further comprise determining a set of equivalence evaluation criteria (EEC) based on the second set of RPWHH, wherein the set of EEC comprises at least 12 EECs, wherein each EEC is determined based on EEC Equations 1, 2, 3, and 5, with η=20%, for each RPWHH in the second set of RPWHH; and determining whether each RPWHH in the first set of RPWHH meets the respective EEC in the set of EEC. In other embodiments, this set of EEC based on RPWHH includes at least one EEC based on at least one RPWHH.

Yet another characterization method uses relative PWHHs (“RWPHH”), which can indicate sameness in terms of physiochemical properties of the carbohydrate particles for purposes of assessing bioequivalence between comparator product and tested iron carbohydrate drug products. As noted, the RPWHH of each of the 12 ¹³C Peaks for the comparator product can be compared quantitatively to the corresponding RPWHH of each of the 12 ¹³C Peaks between the comparator product and tested iron sucrose drug products. The same technique may be applied to other iron carbohydrate drug products such as e.g. high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®).

The RPWHH of each of the n ¹³C Peak can be determined, wherein n is the number of carbon atoms in the carbohydrate. The RPWHH is defined as wⱼ/wₒ, where wₒ is the PWHH for free carbohydrate (carbohydrate only, no iron), and wⱼ is the PWHH for the respective iron carbohydrate drug products, such as the comparator product and the tested product.

In certain embodiments for evaluating RPWHH, the EEC can be determined based on the EEC Equations disclosed herein. In some embodiments, the EEC Equations can be EEC Equations 1, 2, 3, and 5 because RPWHH has multiple parameters, one peak for each corresponding ¹³C NMR peak, and thus, a minimum of η=20% can be used across all n parameters, wherein n is the number of carbon atoms in the carbohydrate.

Thus, in some embodiments, the methods for characterizing iron carbohydrates comprise performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product; performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate of interest, such as e.g. high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®); and performing ¹³C NMR on a third sample to produce a third ¹³C NMR spectrum, wherein the third sample comprises a plurality of carbohydrate particles, and the third sample does not include any iron particle (i.e. the third sample only contains the carbohydrate of the iron carbohydrate of interest).

In other embodiments, after ¹³C NMR are performed on the three samples, the methods further comprise determining a first set of peak width at half-height (PWHH) having at least n PWHHs, wherein each PWHH corresponds to a ¹³C Peak on the first ¹³C NMR spectrum, and wherein the PWHH is a width at a half-height of the ¹³C Peak; determining a second set of PWHH having at least n PWHHs, wherein each PWHH corresponds to a ¹³C Peak on the second ¹³C NMR spectrum; and determining a third set of PWHH having at least n PWHHs, wherein each PWHH corresponds to a ¹³C Peak on the third ¹³C NMR spectrum, wherein n is the number of carbon atoms in the carbohydrate.

In alternate embodiments, after the three sets of PWHHs are determined for the three samples, the methods further comprise determining a first set of relative PWHH (“RPWHH”) having at least n RPWHHs, wherein each RPWHH is the respective PWHH from the first set of PWHH divided by the corresponding PWHH from the third set of PWHH; determining a second set of RPWHH having at least n RPWHHs, wherein each RPWHH is the respective PWHH from the second set of PWHH divided by the corresponding PWHH from the third set of PWHH; and analyzing the first and second sets of RPWHHs by comparing the first set of RPWHH to the second set of RPWHH, wherein n is the number of carbon atoms in the carbohydrate. In some embodiments, the set of RPWHHs includes at least one RPWHH.

In certain embodiments, the analyzing step of the methods further comprise determining a set of equivalence evaluation criteria (EEC) based on the second set of RPWHH, wherein the set of EEC comprises at least n EECs, wherein each EEC is determined based on EEC Equations 1, 2, 3, and 5, with η=20%, for each RPWHH in the second set of RPWHH; and determining whether each RPWHH in the first set of RPWHH meets the respective EEC in the set of EEC, wherein n is the number of carbon atoms in the carbohydrate. In other embodiments, this set of EEC based on RPWHH includes at least one EEC based on at least one RPWHH.

C. Iron Core Characterization Using RPWHH of Sucrose in Iron Sucrose.

In an exemplary embodiment, the method for characterizing iron carbohydrate complex, such as iron sucrose, comprises the steps of performing ¹³C NMR on a first set of samples to produce a corresponding first set of ¹³C NMR spectra, wherein the first set of samples comprises at least three (3) different concentrations of iron in a first sample, wherein the first sample comprises a plurality of iron sucrose particles having an iron core particle and a plurality of sucrose particles surrounding the iron core particle, and wherein the first sample is a tested iron sucrose drug product; performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron sucrose particles having an iron core particle and one or more sucrose particles surrounding the iron core particle, and wherein the second sample is a comparator product for iron sucrose; and performing ¹³C NMR on a third sample to produce a third ¹³C NMR spectrum, wherein the third sample comprises a plurality of sucrose particles, and the third sample does not include any iron particle.

In some embodiments, after NMR are performed on the three samples, then the methods further include determining, for each concentration of the first sample, an average value of a first set of peak width at half-height (PWHH), wherein the PWHH is a width at a half-height of the ¹³C Peak, wherein the first set of PWHH comprises at least twelve PWHHs, each PWHH corresponding to each ¹³C Peak in the respective ¹³C NMR spectrum of the first set of the ¹³C NMR spectra, and wherein the average value is the mean of the at least twelve PWHHs; determining, for each concentration of the second sample, the average value of a second set of PWHH, wherein the second set of PWHH comprises at least twelve PWHHs, each PWHH corresponding to each ¹³C Peak in the respective ¹³C NMR spectrum of the second set of the ¹³C NMR spectra; and determining the average value of a third set of PWHH, wherein the third set of PWHH comprises at least twelve PWHHs, each PWHH corresponding to each ¹³C Peak in the third ¹³C NMR spectrum. In other embodiments, the set of PWHH includes at least one PWHH.

In some embodiments, after the average values of the PWHHs for the three samples are determined, the methods further include determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH; and determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH. In other embodiments, the set of RPWHH includes at least one RPWHH.

In some embodiments, the methods further comprise the step of plotting a graph having the concentration of iron (mg/mL) as an X-axis, and the RPWHHs as a Y-axis, using the first and the second sets of RPWHH. In some embodiments, the correlation coefficient is at least about 0.98. In other embodiments, the correlation coefficient is at least about 0.%, at least about 0.97, or at least about 0.99.

In some embodiments, the methods further comprise the steps of determining a set of equivalence evaluation criteria (EEC) based on the second set of RPWHH, wherein the set of EEC comprises at least 3 EECs, wherein each EEC is determined based on EEC Equations 1, 2, 3, and 4, with η=20% for each RPWHH in the second set of RPWHH; and determining whether each RPWHH in the first set of RPWHH meets the respective EEC in the set of EEC. In other embodiments, the set of EEC includes at least one EEC based on at least one RPWHH. In other embodiments, the EEC can be determined based on one or more of the other EEC Equations.

In some embodiments, the methods further comprise at least five different concentrations of iron in iron sucrose, including, but not limited to, concentrations includes about 0 mg base/mL, about 0.1 mg/mL, about 0.4 mg/mL, about 0.8 mg/mL, or about 2 mg/mL of iron in iron sucrose. In other embodiments, the methods further comprise at least six different concentrations of iron in iron sucrose, including, but not limited to, about 0 mg/mL, about 0.1 mg/mL, about 0.4 mg/mL, about 0.8 mg/mL, about 2 mg/mL, and about 3.2 mg/mL, of iron in iron sucrose. In still other embodiments, the methods further comprise at least eight different concentrations, including, but not limited to, about 0 mg/mL, about 0.03 mg/mL, about 0.1 mg/mL, about 0.2 mg/mL, about 0.4 mg/mL, about 0.8 mg/mL, about 2 mg/mL, and about 3.2 mg/mL of iron in iron sucrose.

Yet another embodiment of the invention is a method for characterizing iron carbohydrate complex such as, e.g. high molecular weight iron dextran (e.g. Dexferrum®), low molecular weight iron dextran (e.g. Cosmofer®), sodium ferric gluconate (e.g. Ferriecit®), iron carboxymaltose (e.g. Ferinject®, Injectafer®), and ferumoxytol (e.g. Feraheme®) comprises the steps of performing ¹³C NMR on a first set of samples to produce a corresponding first set of ¹³C NMR spectra, wherein the first set of samples comprises at least three (3) different concentrations of iron in a first sample, wherein the first sample comprises a plurality of iron carbohydrate particles having an iron core particle and a plurality of carbohydrate particles surrounding the iron core particle, and wherein the first sample is a tested iron carbohydrate drug product; performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron carbohydrate particles having an iron core particle and one or more carbohydrate particles surrounding the iron core particle, and wherein the second sample is a comparator product for the iron carbohydrate of interest (i.e. the iron carbohydrate being tested); and performing ¹³C NMR on a third sample to produce a third ¹³C NMR spectrum, wherein the third sample comprises a plurality of carbohydrate particles, and the third sample does not include any iron particle.

In certain embodiments of these methods, after NMR are performed on the three samples, the methods further include determining, for each concentration of the first sample, an average value of a first set of peak width at half-height (PWHH), wherein the PWHH is a width at a half-height of the ¹³C Peak, wherein the first set of PWHH comprises at least n PWHHs, each PWHH corresponding to each ¹³C Peak in the respective ¹³C NMR spectrum of the first set of the ¹³C NMR spectra, and wherein the average value is the mean of the at least twelve PWHHs; determining, for each concentration of the second sample, the average value of a second set of PWHH, wherein the second set of PWHH comprises at least n PWHHs, each PWHH corresponding to each ¹³C Peak in the respective ¹³C NMR spectrum of the second set of the ¹³C NMR spectra; and determining the average value of a third set of PWHH, wherein the third set of PWHH comprises at least n PWHHs, each PWHH corresponding to each ¹³C Peak in the third ¹³C NMR spectrum, wherein n is the number of carbon atoms in the carbohydrate. In other embodiments, the set of PWHH includes at least one PWHH.

In some embodiments, after the average values of the PWHHs for the three samples are determined, the methods further include determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH; and determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH. In other embodiments, the set of RPWHH includes at least one RPWHH.

In yet other embodiments, the methods may also include plotting a graph having the concentration of iron (mg/mL) as an X-axis, and the RPWHHs as a Y-axis, using the first and the second sets of RPWHH. In some embodiments, the correlation coefficient is at least about 0.98. In other embodiments, the correlation coefficient is at least about 0.96, at least about 0.97, or at least about 0.99.

In alternate embodiments, the methods further include determining a set of equivalence evaluation criteria (EEC) based on the second set of RPWHH, wherein the set of EEC comprises at least 3 EECs, wherein each EEC is determined based on EEC Equations 1, 2, 3, and 4, with η=20% for each RPWHH in the second set of RPWHH; and determining whether each RPWHH in the first set of RPWHH meets the respective EEC in the set of EEC. In other embodiments, the set of EEC includes at least one EEC based on at least one RPWHH. In other embodiments, the EEC can be determined based on one or more of the other EEC Equations.

In some embodiments, the methods further comprise at least five different concentrations of iron in iron carbohydrate, including, but not limited to, concentrations includes about 0 mg base/mL, about 0.1 mg/mL, about 0.4 mg/mL, about 0.8 mg/mL, or about 2 mg/mL of iron in iron carbohydrate. In yet another embodiments, the methods further comprise at least six different concentrations of iron in iron carbohydrate, including, but not limited to, about 0 mg/mL, about 0.1 mg/mL, about 0.4 mg/mL, about 0.8 mg/mL, about 2 mg/mL, and about 3.2 mg/mL, of iron in the iron carbohydrate complex being investigated. In alternate embodiments, the methods further comprise at least eight different concentrations, including, but not limited to, about 0 mg/mL, about 0.03 mg/mL, about 0.1 mg/mL, about 0.2 mg/mL, about 0.4 mg/mL, about 0.8 mg/mL, about 2 mg/mL, and about 3.2 mg/mL of iron in the iron carbohydrate complex being investigated.

D. Characterization of Sucrose Change Over Time Using ¹H NMR of Sucrose in Iron Sucrose.

In alternate embodiments, the methods for characterizing the reduction of an iron carbohydrate complex, such as iron sucrose, uses ¹H NMR. H NMR refers to hydrogen-1 (or proton) nuclear magnetic resonance and can be used to analyze hydrogen (H) atoms in a molecule. In principle, a reducing agent, such as sodium metabisulfite, is applied to the iron sucrose sample, which reduces Fe(III) to Fe (II) in the iron core of the iron sucrose sample. In turn, as the iron core particle is being reduced from Fe(III) to Fe (II), the proton peak (or ¹H peak) of the H atoms in the sucrose should also increase because of the weakened intrinsic magnetic effect from Fe(III). Thus, ¹H NMR can be applied to the iron sucrose sample to monitor the ¹H peak intensity change of one or more H atoms in sucrose, which is indicative of the reduction of the iron core particle from Fe(III) to Fe (II). The same principle is applicable to other iron carbohydrate compounds such as, e.g. high molecular weight iron dextran (e.g. Dexferrum®), low molecular weight iron dextran (e.g. Cosmofer®), sodium ferric gluconate (e.g. Ferrlecit®), iron carboxymaltose (e.g. Ferinject®, Injectafer®), and ferumoxytol (e.g. Feraheme®). Accordingly, the iron core reduction can be analyzed without directly measuring the iron core itself.

In some embodiments, the methods include the steps of applying a reducing agent to one or more first samples, wherein the first sample comprises a plurality of iron sucrose particles having an iron core particle and a plurality of sucrose particles surrounding the iron core particle, wherein the first sample is a tested iron sucrose drug product, wherein the reducing agent reduces the iron core from iron (III) to iron (II), performing ¹H NMR to at least one ¹H in the first sample for a NMR analysis time period, wherein the at least one ¹H is an ¹H associated with the sucrose particle, and during the NMR analysis time period, the reducing agent is reducing iron(III) to iron(II) of the iron core particle of the first sample; applying the reducing agent to one or more second samples, wherein the second sample comprises a plurality of iron sucrose particles having an iron core particle and a plurality of sucrose particles surrounding the iron core particle, wherein the second sample is a comparator product for iron sucrose, wherein the reducing agent reduces the iron core particle from iron (111) to iron (11); performing ¹H NMR to at least one ¹H on the second sample for the NMR analysis time period, wherein the at least one ¹H is the same ¹H associated with the sucrose particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples.

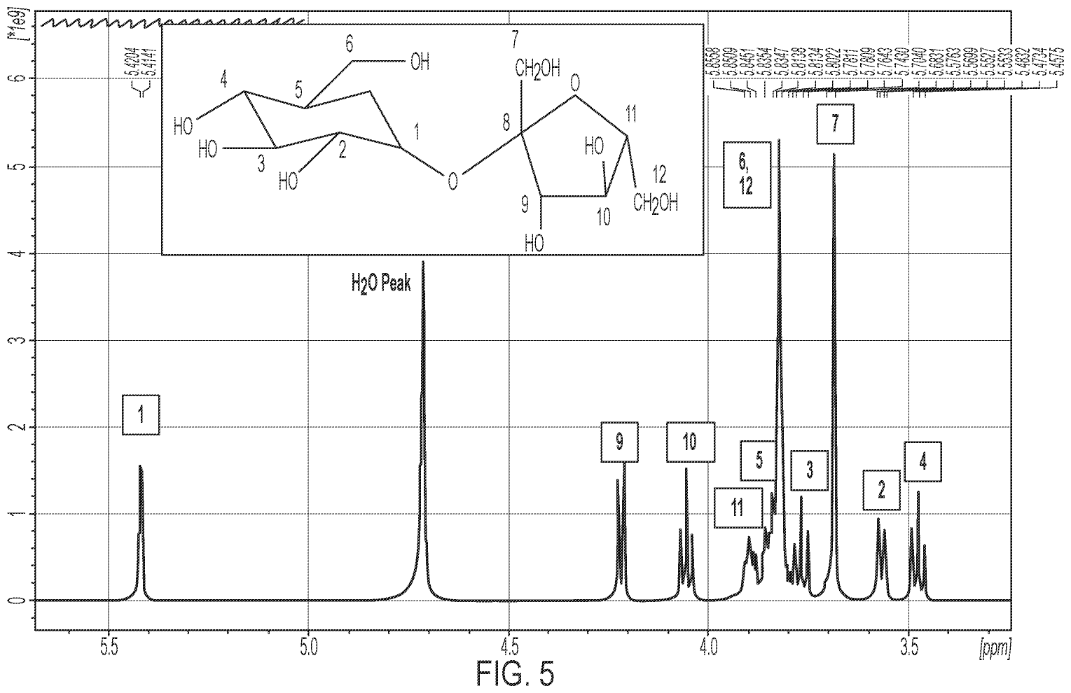

In some embodiments, the at least one ¹H is the hydrogen (H) atom bonded to the C atom identified as 1 in FIG. 1 and has a chemical shift of about 5.4 parts per million (ppm), as shown in FIG. 5. In some embodiments, the at least one ¹H associated with the sucrose particle has a chemical shift of about 5.3 parts per million (ppm) to about 5.5 ppm, including, but not limited, to about 5.3 ppm, about 5.35 ppm, about 5.378 ppm, about 5.40 ppm, about 5.45 ppm, or about 5.5 ppm. In other embodiments, the at least one ¹H is the H atom can be any other H atom associated with the sucrose particle, including the H atoms shown in FIG. 5.

In alternate embodiments, the methods include the steps of applying a reducing agent to one or more first samples, wherein the first sample comprises a plurality of iron carbohydrate particles having an iron core particle and a plurality of carbohydrate particles surrounding the iron core particle, wherein the first sample is a tested iron carbohydrate drug product, wherein the reducing agent reduces the iron core from iron (III) to iron (II); performing ¹H NMR to at least one ¹H in the first sample for a NMR analysis time period, wherein the at least one ¹H is an ¹H associated with the carbohydrate, and during the NMR analysis time period, the reducing agent is reducing iron(III) to iron(II) of the iron core particle of the first sample; applying the reducing agent to one or more second samples, wherein the second sample comprises a plurality of iron carbohydrate particles having an iron core particle and a plurality of carbohydrate particles surrounding the iron core particle, wherein the second sample is a comparator product for the iron carbohydrate, wherein the reducing agent reduces the iron core particle from iron (III) to iron (11); performing ¹H NMR to at least one ¹H on the second sample for the NMR analysis time period, wherein the at least one ¹H is the same ¹H associated with the carbohydrate particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples. In certain embodiments, the comparator product for the iron carbohydrate may be Dexferrum®, Cosmofer®, Ferrlecit®, Ferinject®, Injectafer®, and Feraheme®.

In some embodiments, the at least one ¹H is the hydrogen (H) atom bonded to the C atom in the carbohydrate has a chemical shift of about 5.4 parts per million (ppm). In other embodiments, the at least one ¹H associated with the carbohydrate particle has a chemical shift of about 5.3 parts per million (ppm) to about 5.5 ppm, including, but not limited, to about 5.3 ppm, about 5.35 ppm, about 5.378 ppm, about 5.40 ppm, about 5.45 ppm, or about 5.5 ppm.

In some embodiments, the methods further include the step of performing a first log plot of the change in the intensity of the ¹H peak over the NMR analysis time period for the first sample; performing a second log plot of the change in the intensity of the ¹H Peak over the NMR analysis time period for the second sample; and wherein the log plots are provided in a log graph having a Y-axis of relative ¹H peak intensity (Log %) and a X-axis of time, wherein relative ¹H peak intensity (Log %) is calculated based on Log (100*(Observed Peak−Final Peak)/(Initial Peak−Final Peak)).

In some embodiments, the Initial Peak is the first measured ¹H peak of the at least one ¹H during an initial NMR analysis time period, and the Final Peak is the highest measured ¹H peak of the at least one ¹H during a latter NMR analysis time period. For example, in some embodiments, the initial NMR analysis time period is from about the 3^{rd} minute to about the 8^{th} minute after ¹H NMR analysis has begun on the respective sample, and the latter NMR analysis time period is from about the 50^{th} minute to about the 100^{th} minute after ¹H NMR analysis has begun on the respective sample. The Observed Peak is the measured ¹H peak of the least one ¹H at a desired time point within the NMR analysis time period. In an exemplary embodiment, the Initial Peak is measured at about the 6^{th} minute, the Final Peak is the highest measured ¹H Peak between about the 75^{th} minute and about the 90^{th} minute, and Observed Peak is measured at any desired time point between about the 6^{th} minute and about the 90^{th} minute. The desired time point can be measured at 2-minute intervals between about the 6^{th} minute through about the 90^{th} minute.

In some embodiments, the NMR analysis time period is at least 15 minutes, at least 30 minutes, at least 60 minutes, at least 80 minutes, at least 90 minutes, or more.

In some embodiments, the methods further comprise the steps of determining a reduction half-life period t_{1/2} for the first sample, and determining a t_{1/2} for the second sample, and t_{1/2} is determined by (Log 50 minus (the respective y-intercept))/(the respective slope). Thus, t_{1/2} is an approximate time (in minutes) at which the ¹H peak intensity of the at least one ¹H (e.g. the ¹H atom at about 5.4 ppm) has increased by about 50 percent during the NMR analysis time period. In turn, the approximate 50% increase of the ¹H peak intensity of the at least one ¹H is indicative of an approximate 50% reduction of the iron(III) to the iron(II) in the iron core particle of the respective sample during the NMR analysis time period.

In some embodiments, the methods further comprise the steps of determining a second reduction half-life period 2t_{1/2}, and a third reduction half-life period 3t_{1/2} for the first sample, and determining a 2t_{1/2} and a 3t_{1/2} for the second sample. The 2t_{1/2} is determined by (Log 25 minus (the respective y-intercept))/(the respective slope). Thus, 2t_{1/2} is an approximate time (in minutes) at which the ¹H peak intensity of the at least one ¹H (e.g. the ¹H atom at about 5.4 ppm) has increased by about 75 percent during the NMR analysis time period. In turn, the approximate 75% increase of the ¹H peak intensity of the at least one ¹H is indicative of an approximate 75% reduction of the iron(III) to the iron (II) in the iron core particle of the respective sample during the NMR analysis time period. The 3t_{1/2} is determined by (Log 12.5 minus (the respective y-intercept))/(the respective slope). Thus, 3t_{1/2} is an approximate time (in minutes) at which the ¹H peak intensity of the at least one ¹H (e.g. the ¹H atom at about 5.4 ppm) has increased by about 87.5 percent during the NMR analysis time period. In turn, the approximate 87.5% increase of the ¹H peak intensity of the at least one ¹H is indicative of an approximate 87.5% reduction of the iron(III) to the iron(II) in the iron core particle of the respective sample during the NMR analysis time period.

To determine EEC, one or more of the EEC Equations can be used. In some embodiments, the method includes determining a set of equivalence evaluation criteria (EEC) based on the second log plot, wherein the set of EEC comprises EEC based on one or more of the t_{1/2}, the 2t_{1/2}, and the 3t_{1/2} from the second log plot, wherein each EEC is determined based on EEC Equations 1, 2, 3, and 4, with η=20%, of the respective parameter of second log plot, and determining whether the corresponding parameter of the first log plot meets the respective EEC in the set of EEC.

In some embodiments, the method further comprises determining a first reduction rate based on the first log plot, and determining a second reduction rate based on the second log plot, wherein the reduction rate is defined as the relative 1H peak intensity (Log %) divided by a period of time (e.g. minutes). In some embodiments, the method further includes determining a set of equivalence evaluation criteria (EEC) based on the second log plot, wherein the set of EEC comprises EEC based on the second reduction rate, wherein each EEC is determined based on EEC Equations 1, 2, 3, and 4, with η=20%, of the respective parameter of second log plot, and determining whether the corresponding parameter of the first log plot meets the respective EEC in the set of EEC.

In some embodiments, the reducing agent is sodium metabisulfite, potassium metabisulfite, (−) ascorbic acid, (+) ascorbic acid, or racemic ascorbic acid. Other suitable reducing agents can also be used, such as sulfite and its salts, hydroxymethanesulfinate and its salts, flavin mononucleotide, catechol and substituted catechol, dithionite, thioglycolate, hydroquinone, lactate, phenol and substituted phenol, citrate, bicarbonate, pyruvate, succinate, fructose, cysteine, thiol, or sorbitol. In certain embodiments, the reducing agent is sodium metabisulfite and the iron carbohydrate is iron sucrose. As illustrated by Example 4, sodium metabisulfite reduces iron sucrose very well.

E. Characterization of Iron Carbohydrates Using T1 NMR of Iron Carbohydrates.

Another characterization method uses T1 NMR which can indicate sameness in terms of physiochemical properties of the iron carbohydrate particles, such as the sucrose particles, for purposes of assessing structural equivalence between comparator product and tested iron carbohydrate drug products. As demonstrated in Example 5, the T1 value for the comparator product can be compared quantitatively to the corresponding T1 value of the tested iron carbohydrate product, such as the tested iron sucrose drug products at ˜4.7 ppm. T1 relaxation is the process by which the net magnetization (M) of a nucleus returns to its initial maximum value (M₀). T1 is measured by the inversion-recovery experiment and T1 is determined by fitting the magnetization curve using an equation as below:

$$M = {M}_{0} * ( 1 - 2 {e}^{- \frac{t}{T 1}} )$$

Accordingly, one embodiment provides for methods of characterizing iron sucrose using T1 NMR of iron sucrose. The methods may include the steps of performing T1 NMR and determining a T1 value on a first sample, wherein the first sample comprises a plurality of iron sucrose particles having an iron core particle and a plurality of sucrose particles surrounding the iron core particle, wherein the first sample is a tested iron carbohydrate drug product:

performing T1 NMR and determining a T1 value on a second sample, wherein the second sample comprises a plurality of iron sucrose particles having an iron core particle and a plurality of sucrose particles surrounding the iron core particle, wherein the second sample is a comparator product for the iron sucrose; and

analyzing the first and second T1 values by comparing the first sample's T1 to the second sample's T1, wherein when the results of the analysis of the first and second T1 are the same or substantially the same the tested iron sucrose drug product and the comparator product for the iron sucrose drug are structurally equivalent.

In certain embodiments of these methods, a T1 value of iron sucrose samples may be measured at ˜4.7 ppm. ˜4.7 PPM may be selected because this peak has highest peak intensity and was shown to have good repeatability. The peak at ˜4.7 ppm is water peak which is from iron sucrose product. See Example 5.

Since the peak at ˜4.7 ppm is water peak which is from iron sucrose product, in certain embodiments, the T1 NMR method actually measures how iron sucrose's structure affect its solvent water's T1 relaxation speed. Since different iron sucrose's structure such as different core structure and sucrose shell structure could affect water's relaxation speed, the methods use H₂O relaxation rate as a probe to monitor iron sucrose product quality.

Another alternate embodiment of the invention is a method for characterizing iron carbohydrate comprising the steps of:

performing T1 NMR and determining a T1 value on a first sample, wherein the first sample comprises a plurality of iron carbohydrate particles having an iron core particle and a plurality of carbohydrate particles surrounding the iron core particle, wherein the first sample is a tested iron carbohydrate drug product;

performing T1 NMR and determining a T1 value on a second sample, wherein the second sample comprises a plurality of iron carbohydrate particles having an iron core particle and a plurality of carbohydrate particles surrounding the iron core particle, wherein the second sample is a comparator product for the iron carbohydrate; and

analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

In another embodiment, the invention provides a method for characterizing iron sucrose comprising the steps of:

performing T1 NMR and ¹H NMR experiments which measure T1 NMR and ¹H NMR relaxation values on a first sample to produce a first NMR relaxation spectrum, wherein the first sample comprises a plurality of iron carbohydrate particles having an iron core particle and a plurality of sucrose particles surrounding the iron core particle, wherein the first sample is a tested iron carbohydrate drug product;

performing T1 NMR and ¹H NMR experiments which can measure T1 NMR and ¹H NMR relaxation values on a second sample to produce a second NMR relaxation spectrum, wherein the second sample comprises a plurality of iron sucrose particles having an iron core particle and a plurality of carbohydrate particles surrounding the iron core particle, wherein the second sample is a comparator product for the iron carbohydrate:

determining relaxation values on a first sample of iron sucrose wherein the first sample is a tested iron carbohydrate drug product;

determining relaxation values on a second sample of iron sucrose wherein the second sample is a comparator product for the iron carbohydrate; and

analyzing relaxation values by comparing the first relaxation values to the second relaxation values, wherein when the results of the analysis of relaxation values are the same or substantially the same the tested iron carbohydrate drug product and the comparator product for iron sucrose are bioequivalent. In certain embodiments, wherein the plurality of sucrose particles serves as a ligand to the iron core particle. The plurality of sucrose particle may be up to about 50 sucrose particles. In certain embodiments, the plurality of sucrose particles surrounds the iron core particle by forming a shell of sucrose particles around the iron core particle.

In one embodiment, the methods may be based on performing 2D T1. Accordingly, another alternate embodiment of the invention is a method for characterizing iron carbohydrate comprising the steps of:

performing 2D T1 and determining T1 value on a first sample, wherein the first sample comprises a plurality of iron sucrose particles having an iron core particle and a plurality of sucrose particles surrounding the iron core particle, wherein the first sample is a tested iron carbohydrate drug product;

performing 2D T1 NMR and determine T1 value on a second sample, wherein the second sample comprises a plurality of iron sucrose particles having an iron core particle and a plurality of sucrose particles surrounding the iron core particle, wherein the second sample is a comparator product for the iron carbohydrate:

analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

### V. Combination with Other Methods

In certain embodiments, the methods of the invention may be used in combination with other methods suitable for characterizing iron carbohydrate drugs in such a way as to demonstrate bioequivalence. For example, the methods of the invention may be used in combination with the methods for characterizing iron core size in iron carbohydrate complexes, such as e.g. iron sucrose, including iron sucrose drug products, using small-angle X-ray scattering disclosed in U.S. Provisional Application No. 63/019,864 (filed on May 4, 2020) and PCT Application No. PCT/US2021/30657 (Docket Number 121967.000004), the disclosures of which are herein incorporated in their entirety as they pertain to methods of characterizing iron carbohydrates via small-angle X-ray scattering.

### VI. Additional Embodiments

Other embodiments of the invention are directed to systems configured to perform the methods of the disclosure. For example, one embodiment of the invention is a nuclear magnetic resonance spectrograph configured to perform the methods of the disclosure.

In yet additional embodiments of the invention include generation of the putative iron carbohydrate drug before testing the compound using the methods of the claimed invention to determine bioequivalence to a comparator product.

Additional embodiments of the invention include a computer program product (embodied on a non-transitory computer readable medium and having code adapted to be executed by a computer to perform the methods of the invention) for determining bioequivalence of a putative iron carbohydrate drug to a comparator product.

Yet another embodiment of the invention is directed to a method of treating iron deficiency anemia comprising identifying an iron carbohydrate product that is structurally equivalent to a comparator product for treating iron deficiency anemia using the methods described herein and administering the iron carbohydrate product to a patient suffering from anemia.

Without further description, it is believed that one of ordinary skill in the art can, using the preceding description and the following illustrative examples, make and utilize the present invention and practice the claimed methods. The following working examples, therefore, specifically point out the preferred embodiments of the present invention and are not to be construed as limiting in any way the remainder of the disclosure.

### EXAMPLES

### Example 1—Characterization of Sucrose in Iron Sucrose Using PWHH and RPWHH of ¹³C Peaks of Sucrose

In Example 1, ¹³C NMR was performed on three (3) samples (e.g 3 lots) of a comparator iron sucrose drug product having an equivalent concentration of 20 mg base/mL, and three (3) samples (e.g 3 lots) of a tested iron sucrose drug product having an equivalent concentration of 20 mg base/mL were analyzed by ¹³C NMR in Example 1. The comparator product was Venofer® having an equivalent concentration of 20 mg base/mL. In addition, ¹³C NMR was also performed on 3 samples (e.g. 3 lots) of free sucrose sample. Free sucrose is sucrose only with no iron.

These ¹³C NMR results are provided in Tables 1 and 2. The average PWHH of the 3 lots of the comparator iron sucrose drug product is identified as w in Tables 1 and 2. The average PWHH of the 3 lots of the tested iron sucrose drug productis identified as w in Tables 1 and 2. The average PWHH of the 3 lots of sucrose only sample is identified as w₀ in Tables 1 and 2.

TABLE 1
PWHH of ¹³C Peaks in Sucrose of Iron Sucrose

| | | | | PWHH, | | |
|---|---|---|---|---|---|---|
| | | Peak Assignment | | three lots mean (in ppb) | | |
| ¹³C | Chemical | | Carbon | Sucrose | CP | Tested Iron |
| Peak | Shift | Carbohydrate | Atom No. | Only | (Venofer ®) | Sucrose |
| No. | (in ppm) | Unit | (see FIG. 1) | (w₀) | (w₁) | (w₂) |
| 1 | 106.0 | Fructose | 8 | 10.6 | 107 | 100 |
| 2 | 95.0 | Glucose | 1 | 14.7 | 122 | 113 |
| 3 | 84.0 | Fructose | 11 | 13.4 | 117 | 107 |
| 4 | 79.0 | Fructose | 9 | 16.3 | 123 | 113 |
| 5 | 76.0 | Fructose | 10 | 15.8 | 122 | 111 |
| 6 | 75.4 | Glucose | 3 | 14.3 | 141 | 143 |
| 7 | 75.2 | Glucose | 5 | 14.9 | 146 | 131 |
| 8 | 73.9 | Glucose | 2 | 15.7 | 126 | 117 |
| 9 | 72.0 | Glucose | 4 | 13.7 | 128 | 116 |
| 10 | 65.2 | Fructose | 7 | 16.2 | 123 | 113 |
| 11 | 64.1 | Fructose | 12 | 17.6 | 133 | 123 |
| 12 | 62.9 | Glucose | 6 | 17.2 | 129 | 117 |

| | | | |
|---|---|---|---|
| Average | 15.0 | 126 | 117 |
| Standard Deviation | 2 | 10 | 11 |

As shown in Table 1, the chemical shifts of the twelve ¹³C Peaks associated with the C atoms in sucrose are provided in parts per million (ppm). The twelve ¹³C Peaks are identified with the corresponding C atom numbers of the sucrose provided in FIG. 1. Also, in Table 1, for each of the 12 C atoms in the sucrose, the average PWHH (3 lots each) of w₁ (comparator product), w₂ (tested drug product), and w₀ (sucrose only) are provided. In sum, the average PWHH is 126±10 parts per billion (ppb) for w₁ (comparator product), 117±11 ppb for w₂ (tested drug product), and 15±2 ppb for w₀ (sucrose only).

Notably, even in the ppb range, the average (3 lots) PWHHs are very close between the comparator product (w₁) and the tested iron sucrose drug product (w₂), which demonstrates that the characterization methods disclosed herein using PWHH are very sensitive parameters that can be used to quantitatively evaluate the sameness of the physiochemical properties between a comparator product and a tested iron sucrose drug product.

TABLE 2
Relative PWHH of ¹³C Peaks in Sucrose of Iron Sucrose

| ¹³C | Chemical | Peak Assignment | | Relative PWHH (RPWHH) | |
|---|---|---|---|---|---|
| Peak | Shift | Carbohydrate | Carbon No. | CP (Venofer ®) | Tested Iron |
| No. | (in ppm) | Unit | (see FIG. 1) | (w₁/wₒ) | Sucrose (w₂/wₒ) |
| 1 | 106.0 | Fructose | 8 | 10.2 | 9.4 |
| 2 | 95.0 | Glucose | 1 | 8.3 | 7.7 |
| 3 | 84.0 | Fructose | 11 | 8.8 | 8.0 |
| 4 | 79.0 | Fructose | 9 | 7.5 | 6.9 |
| 5 | 76.0 | Fructose | 10 | 7.7 | 7.0 |
| 6 | 75.4 | Glucose | 3 | 9.9 | 10.0 |
| 7 | 75.2 | Glucose | 5 | 9.8 | 8.8 |
| 8 | 73.9 | Glucose | 2 | 8.0 | 7.4 |
| 9 | 72.0 | Glucose | 4 | 9.3 | 8.5 |
| 10 | 65.2 | Fructose | 7 | 7.6 | 7.0 |
| 11 | 64.1 | Fructose | 12 | 7.6 | 7.0 |
| 12 | 62.9 | Glucose | 6 | 7.5 | 6.8 |

| | | |
|---|---|---|
| Average | 8.5 | 7.9 |
| Standard Deviation | 1.0 | 1.1 |

In addition to PWHH, a RPWHH is another characterization method disclosed herein. Table 2 shows the RPWHH for the comparator product, Venofer® (w₁) and the tested iron sucrose drug product (w₂) for each of the twelve (12) C atoms associated with sucrose. w₁/wₒ is the RPWHH when the respective comparator product (w₁) PWHH is divided by the corresponding PWHH for sucrose only (wₒ). w₂/wₒ is the RPWHH when the respective tested iron sucrose drug product (w₂) PWHH is divided by the corresponding PWHH for sucrose only (wₒ). As provided in Table 1, the RPWHH averaged among the twelve (12) C peaks and the 3 lots for: (i) w₁/wₒ is 8.5 f 1.0, and (ii) w₂/wₒ is 7.9±1.1.

Notably, even in the ppb range, the RPWHHs are very close between the comparator product (w₁) and the tested iron sucrose drug product (w₂), which demonstrates that the methods disclosed herein using the RPWHHs are very sensitive parameters that can be used to quantitatively evaluate the sameness of the physiochemical properties between a comparator product and a tested iron sucrose drug product.

### Example 2—Characterization of Sucrose in Iron Sucrose Using RPWHH of ¹³C Peaks of Sucrose

Example 2 is another example for characterizing the sucrose in iron sucrose using RPWHH of ¹³C Peaks of Sucrose. In Example 2, ¹³C NMR were performed on six (6) samples (e.g. 6 lots) of a comparator product iron sucrose drug product having an equivalent concentration of 20 mg base/mL, six (6) samples (e.g. 6 lots) of a tested iron sucrose drug product having an equivalent concentration of 20 mg base/mL, and 30% free sucrose (300 mg/mL). The comparator product was Venofer® having an equivalent concentration of 20 mg base/mL.

In the ¹³C NMR analysis, each sample was made of 100 μL of iron sucrose drug product injection and 0.1% TSP-d4 in 900 μL of D₂O (deuterium oxide) to ensure the structure integrity of iron-sucrose complex particles and was shimmed to ensure final BO standard deviation is less than 0.5 Hz. The ¹³C NMR spectra was acquired on a Bruker Avance 600 MHz instrument equipped with a 5 mm CPDCH ¹³C/D-¹H Z-GRD probe and collected with a zgpg pulse program. These ¹³C NMR results are provided in FIG. 3 and Tables 3-4.

TABLE 3
¹³C NMR Chemical Shifts in Sucrose of Iron Sucrose

| | Chemical Shift (ppm) | | | | | | | | | | | | |
|---|---|---|---|---|---|---|---|---|---|---|---|---|---|
| | | Peak No. (FIG. 3) | | | | | | | | | | | |
| | | 1 | 2 | 3 | 4 | 5 | 6 | 7 | 8 | 9 | 10 | 11 | 12 |
| | | Carbon No. (FIG. 1) | | | | | | | | | | | |
| Product/Item | | C2′ | C1 | C5′ | C3′ | C4′ | C3 | C5 | C2 | C4 | C1′ | C6′ | C6 |
| CP Iron | Lot | 106.5 | 95.0 | 84.2 | 79.2 | 76.8 | 75.4 | 75.2 | 73.9 | 72.0 | 65.2 | 64.1 | 62.9 |
| Sucrose | 7130A | | | | | | | | | | | | |
| (Venofer ®) | Lot | 106.5 | 95.0 | 84.2 | 79.2 | 76.8 | 75.4 | 75.2 | 73.9 | 72.0 | 65.2 | 64.1 | 62.9 |
| | 7300A | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 7316P | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 7246 | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 8147 | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 8212 | | | | | | | | | | | | |
| CP | Extreme- | 0% | 0% | 0% | 0% | 0% | 0% | 0% | 0% | 0% | 0% | 0% | 0% |
| Assessment | range | | | | | | | | | | | | |
| | (E-range) | | | | | | | | | | | | |
| EEC | δ (ppm) | 0.5 | 0.5 | 0.5 | 0.5 | 0.5 | 0.5 | 0.5 | 0.5 | 0.5 | 0.5 | 0.5 | 0.5 |
| | Lower | 106.0 | 94.5 | 83.7 | 78.7 | 76.3 | 74.9 | 74.7 | 73.4 | 71.5 | 64.7 | 63.6 | 62.4 |
| | Upper | 107.0 | 95.5 | 84.7 | 79.7 | 77.3 | 75.9 | 75.7 | 74.4 | 72.5 | 65.7 | 64.6 | 63.4 |
| Tested | Lot | 106.5 | 95.0 | 84.2 | 79.2 | 76.8 | 75.4 | 75.2 | 73.9 | 72.0 | 65.2 | 64.1 | 62.9 |
| Iron | 121317B | | | | | | | | | | | | |
| Sucrose | Lot | 106.5 | 95.0 | 84.2 | 79.2 | 76.8 | 75.4 | 75.2 | 73.9 | 72.0 | 65.2 | 64.1 | 62.9 |
| | 011218B | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 01271B | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 020818A | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 030118A | | | | | | | | | | | | |
| | Lot | 106.5 | 95.0 | 84.2 | 79.2 | 76.8 | 75.4 | 75.2 | 73.9 | 72.0 | 65.2 | 64.1 | 62.9 |
| | 030818A | | | | | | | | | | | | |

In Table 3, the Peak No. corresponds to the Peak Nos. shown in FIG. 3 and the Carbon No. corresponds to the Carbon Nos. shown in FIG. 1. The 6 lots of the comparator iron sucrose drug product are identified as Lot 7130A, Lot 7300A, Lot 7316P, Lot 7246, Lot 8147, and Lot 8212. In Table 1. The 6 lots of the tested iron sucrose drug product are identified as Lot 121317B, Lot 011218B, Lot 01271B, Lot 020818A, Lot 030118A, and Lot 030818A. EEC Equations 6 and 7, with 8 being 0.5 ppm (parts per million), were used to determine EEC because the chemical measurement in ¹³C NMR is extremely sensitive and the data results are at very low levels.

Notably, as shown in Table 3, all 6 tested iron sucrose lots fall within the EEC criteria for all Peak Nos. and all Carbon Nos. Therefore, all of the above ¹³C NMR analysis results for the chemical shift of carbon atoms listed in Table 3 and FIG. 3 have corroborated the sameness between the comparator iron sucrose drug product and the tested iron sucrose drug product for the molecular environment and surface properties of the sucrose shell.

TABLE 4
RPWHH of ¹³C Peaks in Sucrose of Iron Sucrose

| | RPWHH (wj/wo) | | | | | | | | | | | | |
|---|---|---|---|---|---|---|---|---|---|---|---|---|---|
| | | Peak No. (FIG. 3) | | | | | | | | | | | |
| | | 1 | 2 | 3 | 4 | 5 | 6 | 7 | 8 | 9 | 10 | 11 | 12 |
| | | Carbon No. (FIG. 1) | | | | | | | | | | | |
| Product/Item | | C2′ | C1 | C5′ | C3′ | C4′ | C3 | C5 | C2 | C4 | C1′ | C6′ | C6 |
| CP Iron | Lot | 16 | 8.0 | 16 | 8.5 | 8.0 | 6.3 | 21 | 8.5 | 8.5 | 5.7 | 9.0 | 8.5 |
| Sucrose | 7130A | | | | | | | | | | | | |
| (Venofer ®) | Lot | 14 | 7.5 | 15 | 7.5 | 8.0 | 7.0 | 19 | 8.0 | 7.5 | 5.0 | 8.5 | 8.0 |
| | 7300A | | | | | | | | | | | | |
| | Lot | 13 | 6.5 | 14 | 7.0 | 6.5 | 6.3 | 17 | 7.0 | 7.5 | 4.7 | 7.5 | 7.0 |
| | 7316P | | | | | | | | | | | | |
| | Lot | 13 | 7.0 | 15 | 7.5 | 7.0 | 6.7 | 19 | 7.5 | 8.0 | 5.0 | 8.0 | 8.0 |
| | 7246 | | | | | | | | | | | | |
| | Lot | 11 | 6.0 | 11 | 6.0 | 6.0 | 5.3 | 14 | 6.0 | 6.0 | 3.7 | 6.5 | 6.5 |
| | 8147 | | | | | | | | | | | | |
| | Lot | 13 | 7.0 | 13 | 7.0 | 7.0 | 6.0 | 20 | 7.5 | 7.5 | 4.7 | 7.5 | 7.5 |
| | 8212 | | | | | | | | | | | | |
| CP | Extreme- | 38% | 29% | 36% | 35% | 28% | 27% | 38% | 34% | 33% | 42% | 32% | 26% |
| Assessment | range | | | | | | | | | | | | |
| | (E-range) | | | | | | | | | | | | |
| EEC | H | 20% | 20% | 20% | 20% | 20% | 20% | 20% | 20% | 20% | 20% | 20% | 20% |
| | Lower | 9 | 4.8 | 9 | 4.8 | 4.8 | 4.3 | 11 | 4.8 | 4.8 | 2.9 | 5.2 | 5.2 |
| | Upper | 19 | 9.6 | 19 | 10 | 9.6 | 8.4 | 25 | 10 | 10 | 6.8 | 11 | 10 |
| Tested | Lot | 16 | 8.0 | 16 | 8.0 | 8.5 | 6.7 | 21 | 9.0 | 9.0 | 5.3 | 9.0 | 8.5 |
| Iron | 121317B | | | | | | | | | | | | |
| Sucrose | Lot | 14 | 7.5 | 15 | 7.5 | 8.0 | 7.0 | 19 | 8.0 | 8.0 | 5.0 | 8.5 | 8.0 |
| | 011218B | | | | | | | | | | | | |
| | Lot | 12 | 7.0 | 13 | 7.0 | 6.5 | 6.3 | 18 | 7.0 | 7.0 | 4.3 | 7.5 | 7.5 |
| | 01271B | | | | | | | | | | | | |
| | Lot | 13 | 7.0 | 14 | 7.0 | 7.0 | 6.7 | 19 | 7.5 | 7.5 | 4.7 | 8.0 | 7.5 |
| | 020818A | | | | | | | | | | | | |
| | Lot | 13 | 7.0 | 14 | 7.0 | 7.0 | 6.3 | 19 | 7.5 | 7.5 | 4.7 | 8.0 | 7.5 |
| | 030118A | | | | | | | | | | | | |
| | Lot | 13 | 7.5 | 14 | 7.5 | 7.0 | 6.7 | 19 | 7.5 | 7.5 | 4.7 | 7.5 | 7.5 |
| | 030818A | | | | | | | | | | | | |

In Table 4, the RPWHH is defined by wⱼ/wo where wⱼ represents the respective PWHH of either the comparator product or tested iron sucrose drug product, and wₒ is the corresponding PWHH for free sucrose. In Example 2, the free sucrose used was 30% free sucrose, which is 300 mg/mL.

To determine EEC, EEC Equations 1, 2, 3, and 5, with a minimum of η=20% was used for all parameters because of the relatively broad variations of the comparator product data due to high sensitivity of PWHH parameter values in the ppb (parts per billion). As shown in Table 4, the obtained RPWHH for the tested iron sucrose drug products meet the EEC for each peak of the sucrose in the all of the 6 lots of the tested iron sucrose drug products and hereby support a quantitative determination of sameness to the comparator product by ¹³C NMR for the sucrose shell surface properties.

### Example 3—Iron Core Characterization Using RPWHH of Sucrose in Iron Sucrose

Example 3 characterizes the iron core in iron sucrose using the RPWHH of sucrose. The RPWHH analysis can be leveraged to study the iron core magnetic effect on sucrose. The average RPWHH of all the twelve (12)¹³C NMR peaks in the tested iron sucrose drug products to that of the 30% (300 mg/mL) free sucrose as the baseline varies with and depends on the concentration and properties of iron core, because the vast majority of iron exists in colloidal core of Fe(III)-hydroxide. Therefore, the iron core magnetic effect on sucrose can be comparatively studied between tested iron sucrose drug product and the comparator product by the method that investigates the 12-peak average RPWHH of ¹³C NMR under a range of different dilutions of iron sucrose drug product.

Thus, similar to Examples 1 and 2, ¹³C NMR was performed on tested iron sucrose drug products, comparator products, and 30% free sucrose (300 mg/mL sucrose). In particular, ¹³C NMR was performed on different concentrations of the iron core (e.g. Fe(III)) for each of six (6) lots of the tested iron sucrose drug product and each of the six (6) lots of the comparator products, and sucrose only. Venofer® is the comparator product used in Example 3. The different concentrations of iron of the iron sucrose drug products are 0 mg/mL, 0.1 mg/mL, 0.4 mg/mL, 0.8 mg/mL, 2.0 mg/mL, and 3.2 mg/mL, as provided in Table 5.

Each sample solution was made of 100 μL of IS injection and 0.125% TSP-d4 in 900 μL of D20. The solution was then diluted by 200 mg/mL free sucrose solution to reach final concentrations of Fe(III) at 0.1 mg/mL, 0.4 mg/mL, 0.8 mg/mL, 2.0 mg/mL, and 3.2 mg/mL. In Example 3, the sample was shimmed to ensure final BO standard deviation is <0.5 Hz. The ¹³C NMR spectra was acquired on a Bruker Avance 600 MHz instrument equipped with a 5 mm CPDCH 13C/D-1H Z-GRD probe and collected with a zgpg pulse program.

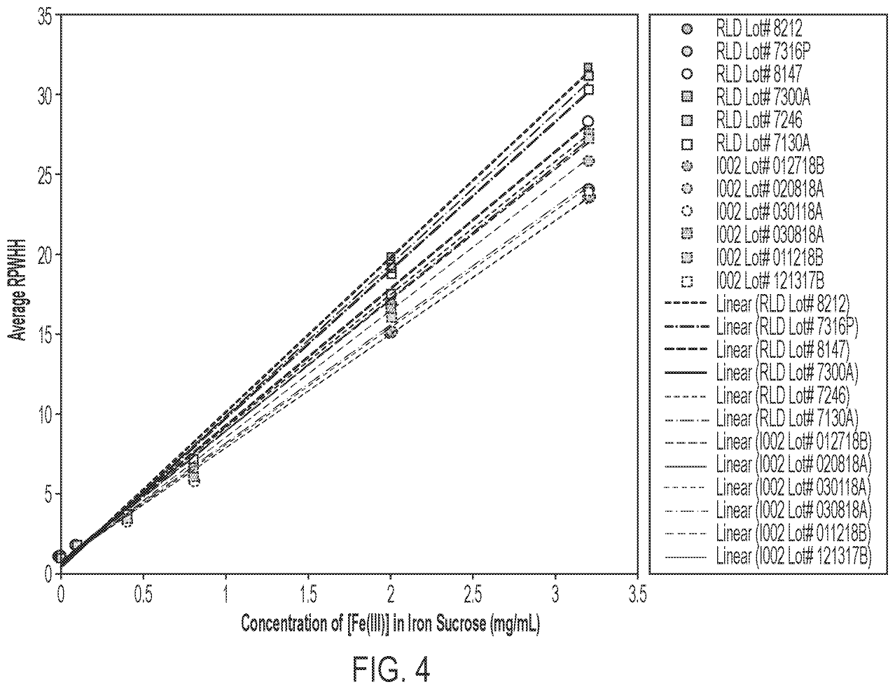

Similar to Examples 1 and 2, twelve (12) ¹³C Peaks were assessed for the PWHH, one PWHH for each different Fe(III) concentration of each lot. Subsequently, the 12 PWHHs for each concentration were averaged. Next, the relative averaged PWHH were determined. The relative averaged PWHH is the averaged PWHH of the iron sucrose drug product (e.g. comparator product or tested) divided by the averaged PWHH of sucrose only. These results are provided in Table 5 and FIG. 4.

TABLE 5
Relative Averaged PWHH for Different Iron Concentrations of Iron Sucrose.

| | 12-Peak Average RPWHH vs. Iron (Fe) Concentration | | | | | | | |
|---|---|---|---|---|---|---|---|---|
| | Iron (Fe) | 0 | 0.1 | 0.4 | 0.8 | 2.0 | 3.2 | |
| Product/Item | Conc. | mg/mL | mg/mL | mg/mL | mg/mL | mg/mL | mg/mL | Slope |
| CP Iron | Lot | 1.0 | 1.6 | 3.7 | 7.0 | 18.8 | 31.2 | 9.5 |
| Sucrose | 7130A | | | | | | | |
| (Venofer ®) | Lot | 1.0 | 1.8 | 3.9 | 6.9 | 19.7 | 31.6 | 9.7 |
| | 7300A | | | | | | | |
| | Lot | 1.0 | 1.5 | 3.2 | 5.7 | 16.5 | 24.1 | 7.5 |
| | 7316P | | | | | | | |
| | Lot | 1.0 | 1.6 | 3.7 | 6.1 | 16.1 | 23.9 | 7.3 |
| | 7246 | | | | | | | |
| | Lot | 1.0 | 1.5 | 3.6 | 6.4 | 17.6 | 28.4 | 8.7 |
| | 8147 | | | | | | | |
| | Lot | 1.0 | 1.6 | 3.7 | 6.1 | 16.8 | 25.9 | 7.9 |
| | 8212 | | | | | | | |
| CP | Extreme- | 0% | 19% | 19% | 20% | 20% | 28% | 28% |
| Assessment | range | | | | | | | |
| | (E-range) | | | | | | | |
| EEC | η | 15% | 15% | 15% | 15% | 15% | 15% | 15% |
| | Lower | 0.9 | 1.3 | 2.7 | 4.8 | 13.7 | 20.3 | 6.2 |
| | Upper | 1.2 | 2.1 | 4.5 | 8.1 | 22.7 | 36.3 | 11.1 |
| Tested | Lot | 1.0 | 1.8 | 3.8 | 7.1 | 19.1 | 30.2 | 9.2 |
| Iron | 121317B | | | | | | | |
| Sucrose | Lot | 1.0 | 1.8 | 3.7 | 6.6 | 17.6 | 27.4 | 8.4 |
| | 011218B | | | | | | | |
| | Lot | 1.0 | 1.7 | 3.7 | 6.3 | 15.2 | 23.6 | 7.1 |
| | 01271B | | | | | | | |
| | Lot | 1.0 | 1.7 | 3.5 | 6.4 | 16.9 | 27.2 | 8.3 |
| | 020818A | | | | | | | |
| | Lot | 1.0 | 1.6 | 3.7 | 6.3 | 15.1 | 23.5 | 7.1 |
| | 030118A | | | | | | | |
| | Lot | 1.0 | 1.6 | 3.6 | 6.2 | 16.7 | 27.6 | 8.3 |
| | 030818A | | | | | | | |

The results of Table 5 are plotted in the graph shown as FIG. 4. EEC Equations 1, 2, 3, and 4, with η=20%, can be used to determine EEC because a relatively higher comparator product's average RPWHH E-range of 28% at 3.2 mg/mL was observed.

Notably, as provided in Table 5, all the tested iron sucrose drug product lots meet the EEC. Also, as shown in FIG. 5, all the tested iron sucrose drug product lots show a linear trend of average RPWHH versus iron concentration comparable to those profiles of the six (6) comparator product lots. It can be concluded that with the same composition of iron and sucrose in both the iron sucrose complex and the entire iron sucrose drug product as reported in Example 3, the sameness between 1002 (the tested iron sucrose) and the comparator product for the magnitude of magnetic effect from the iron core on sucrose is observed.

### Example 4—Characterization of Reduction Kinetics in Iron Sucrose by Determining Carbohydrate Change Using ¹H NMR of Sucrose

An example of another characterization of iron sucrose is a quantitative characterization of reduction kinetics of iron sucrose by determining the carbohydrate change in an iron carbohydrate complex, such as iron sucrose, using ¹H NMR. In particular, the carbohydrate change is focused on the sucrose ¹H peak intensity change at a ¹H peak having a chemical shift of about 5.4 ppm. The ˜5.4 ppm ¹H peak is identified as “1” in the ¹H NMR spectrum of sucrose in FIG. 5, and also identified as “1” in the chemical structure of sucrose in FIG. 5. The ˜5.4 ppm ¹H peak was selected because the other sucrose ¹H peaks may be overlapped or distorted by the peaks of a reducing agent.

The ¹H peak of sucrose at about 5.4 ppm is used to monitor the peak broadening induced by paramagnetic iron core in an iron sucrose drug product. After reducing the iron core particle from ferric, Fe(III), to ferrous, Fe(II), with a reducing agent, such as sodium metabisulfite, the ¹H peak intensity should increase. Thus, this ¹H peak intensity change can be used to calculate t_{1/2}, 2t_{1/2}, and 3t_{1/2}, which are parameters indicative of the reduction of Fe(III) to Fe(II) in the iron core particle by about 50%, 75%, and 87.5%, respectively, during the NMR analysis time period.

In Example 4, ¹H NMR was performed on six (6) lots of tested iron sucrose drug product having an equivalent concentration of about 20 mg/mL of iron, and six (6) lots of comparator iron sucrose drug product (Venofer®) having an equivalent concentration of about 20 mg/mL of iron, as shown in Table 6.

For each of the 12 respective lots, the sample was prepared as follow: (1) 25 μL of 10-fold D₂O diluted iron sucrose drug product injection, (2) 0.275 mL of D₂O containing 0.9% NaCl and 0.1% TSP-d4, (3) 0.2 mL 80% Na₂S₂O₅ solution in D₂O, and (4) 50 μL 8.3% diluted DCl (Deuterium Chloride) solution in D₂O. Next, the mixed solution was then shimmed to ensure final BO standard deviation is less than 0.5 Hz. The ¹H NMR peak intensity was continuously collected by a zg pulse program with 2 min interval up to 90 min after mixing for 6 min on a Bruker Avance 600 MHz instrument equipped with a 5 mm CPDCH 13C/D-1H Z-GRD probe that had been preheated to 40° C.

The kinetics of Fe(III) reduction was obtained by calculating the relative ¹H peak intensity of ¹H NMR of sucrose using the following equation:

$$Relative peak intensity ( Log \% ) = Log [ \frac{{Obs}_{Int} - {Final}_{Int}}{{Initial}_{Int} - {Final}_{Int}} \times 100 ]$$

where,
Obs_{Int}=Observed sucrose peak intensity at about 5.378 ppm at different time;
Initial_{Int}=1ₛₜ acquired sucrose peak intensity at about 5.378 ppm (6 min); and
Final_{Int}=Highest sucrose peak intensity during 60 minutes to 90 minutes at about 5.378 ppm.

The Initial Peak was first measured at about the 6^{th} minute after NMR analysis has begun on the respective sample. After about the 6ₜₕ minute, the Observed Peaks were measured at about 2-minute intervals for up to about the 6^{th} minute. The Final Peak was observed as the highest peak between about the 75^{th} to about the 90^{th} minute after NMR analysis has begun. Therefore, Example 4 has an NMR analysis time period of about 90 minutes, an initial NMR analysis time period of(about the 6^{th} minute, and a latter NMR analysis time period of about the 75^{th} minute to about the 90^{th} minute.

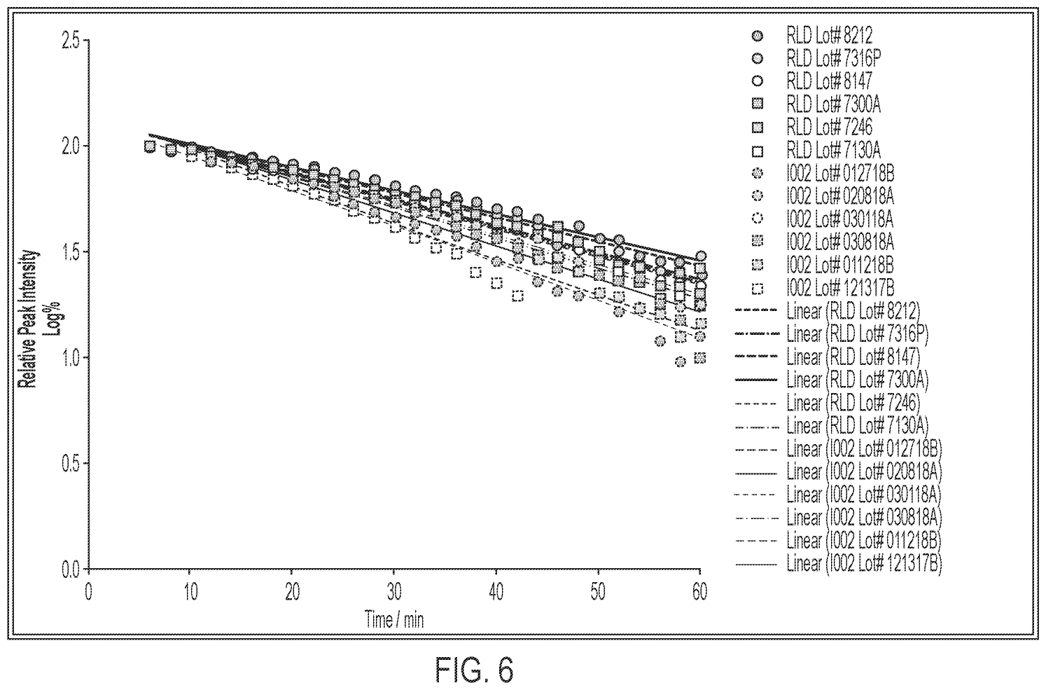

Table 6 and FIG. 6 provide the ¹H NMR results and corresponding log plots for each of 12 iron sucrose drug product lots described in Example 4.

TABLE 6
¹H Peak Intensity NMR Results for Comparator Product and
Tested Iron Sucrose Drug Products Lots in Example 4.

| | Fe(III) Reduction by ¹H NMR | | | | |
|---|---|---|---|---|---|
| Product/ | Kinetic | | | | Reduction Rate |
| Item | Parameters | t_{1/2}/min | 2t_{1/2}/min | 3t_{1/2}/min | (Log %/min) |
| CP Iron | Lot 7130A | 31 | 52 | 73 | −1.5% |
| Sucrose | Lot 7300A | 29 | 49 | 68 | −1.6% |
| (Venofer ®) | Lot 7316P | 34 | 58 | 82 | −1.3% |
| | Lot 7246 | 33 | 56 | 79 | −1.3% |
| | Lot 8147 | 37 | 63 | 89 | −1.2% |
| | Lot 8212 | 26 | 43 | 60 | −1.8% |
| CP | Extreme-range | 34% | 38% | 39% | 44% |
| Assessment | (E-range) | | | | |
| EEC | η | 25% | 25% | 25% | 25% |
| | Lower | 20 | 32 | 45 | −2.3% |
| | Upper | 47 | 79 | 11 | −0.9% |
| Tested Iron | Lot 121317B | 37 | 63 | 90 | −1.1% |
| Sucrose | Lot 011218B | 25 | 44 | 62 | −1.6% |
| | Lot 01271B | 39 | 66 | 93 | −1.1% |
| | Lot 020818A | 32 | 53 | 74 | −1.4% |
| | Lot 030118A | 34 | 58 | 82 | −1.3% |
| | Lot 030818A | 34 | 57 | 80 | −1.3% |

Table 6 shows the ¹H NMR results for six (6) lots each of the tested and comparator iron sucrose drug products tested in Example 4, and in particular, the parameters of the reduction half-life periods of t_{1/2}, 2t_{1/2}, and 3t_{1/2}, and the reduction rate (Log %/min). More particularly, the reduction rate is defined as relative ¹H peak intensity (Log %) per minute. These parameters are derived from the corresponding log percentage (%) plots of the ¹H peak intensity change of the ¹H atom at about 5.4 ppm during the reduction of iron(III) to iron(II), as shown in FIG. 6.

To determine EEC, EEC Equations 1, 2, 3, and 4, with η=25%, because a highly fluctuated E-range between 34% to 44% for all the kinetic parameters of the comparator product was observed. As shown in Table 6, all 6 lots of the tested iron sucrose drug product met the EEC for the parameters of t_{1/2}, 2t_{1/2}, 3t_{1/2}, and the reduction rate (Log %/min), which demonstrates sameness of Fe(III) reduction kinetics in the iron core particle between the tested iron sucrose drug product and the comparator product.

FIG. 6 shows the corresponding log percentage (%) plots of the ¹H peak intensity change of the ¹H atom at about 5.4 ppm during the reduction of iron(III) to iron(II) for Example 4. In FIG. 6, the x-axis represents the time in minutes, and the y-axis represents the relative ¹H peak intensity (Log %), which is defined as the Log (100*(Observed Peak−Final Peak)/(Initial Peak−Final Peak)). In Example 4, the Initial Peak is the ¹H peak intensity measured at about the 6^{th} minute, the Final Peak is the highest measured ¹H peak intensity between about the 75^{th} to about the 90^{th} minute, and Observed Peak are the measured ¹H peaks, at 2-minute intervals, in the time period between the 6^{th} minute and the 60^{th} minute. Notably, as shown in FIG. 6, the Fe(III) reduction kinetic curves of all the tested iron sucrose drug product lots have similar linear, range-overlaid trends as compared to those of the six (6) comparator product lots.

### Example 5—Characterization of Iron Sucrose Using T1 NMR of Iron Sucrose

NMR relaxation is a key NMR process by which nuclei return to equilibrium magnetic state from excited magnetic state. Nucleus relaxation is sensitive to chemical environment change, especially change of paramagnetic Fe(III). Since PWHH is reciprocal of the T2 because of famous Heisenberg's Uncertainty Principle in quantum mechanics, PWHH is as important as T2. Small structure change from iron core or sucrose shell could change relaxation speed of sucrose and water. There are two type of relaxation: T1 (spin-lattice relaxation) and T2 (spin-spin relaxation). So far, relaxation T1 and T2 have not been studied for iron carbohydrates.

T1 relaxation is the process by which the net magnetization (M) of a nucleus returns to its initial maximum value (M₀). T1 is measured by an inversion-recovery experiment and is determined by fitting the magnetization curve using an equation as below:

$$M = {M}_{0} * ( 1 - 2 {e}^{- \frac{t}{T 1}} )$$

T1 NMR were performed on three (3) samples (e.g. 3 lots) of a comparator product iron sucrose drug product having an equivalent concentration of 20 mg base/mL, six (6) samples (e.g. 6 lots) of a tested iron sucrose drug product having an equivalent concentration of 20 mg base/mL. The comparator product was Venofer having an equivalent concentration of 20 mg base/mL.

In the T1 NMR analysis, each sample was made of 10 μL of iron sucrose drug product injection and 990 μL of D₂O (deuterium oxide) containing 0.01% TSP. The NMR was shimmed to ensure final BO standard deviation is less than 0.5 Hz. The T1 NMR spectra was acquired on a Bruker Avance 500 MHz instrument equipped with a 5 mm TCI ¹H/¹³C/¹⁵N Cryo probe and collected with a tlir pulse program. These T1 NMR results are provided in Table 7 as shown below.

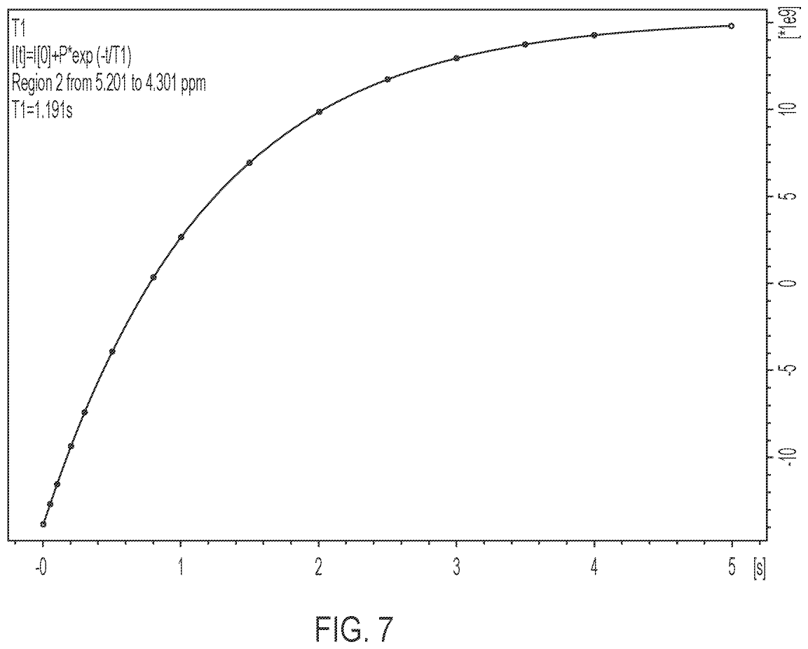

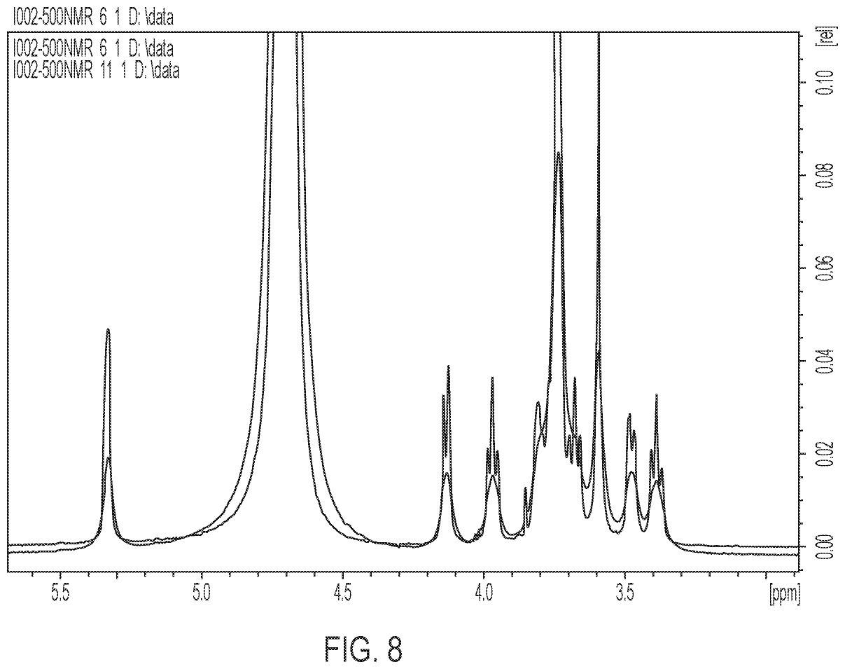

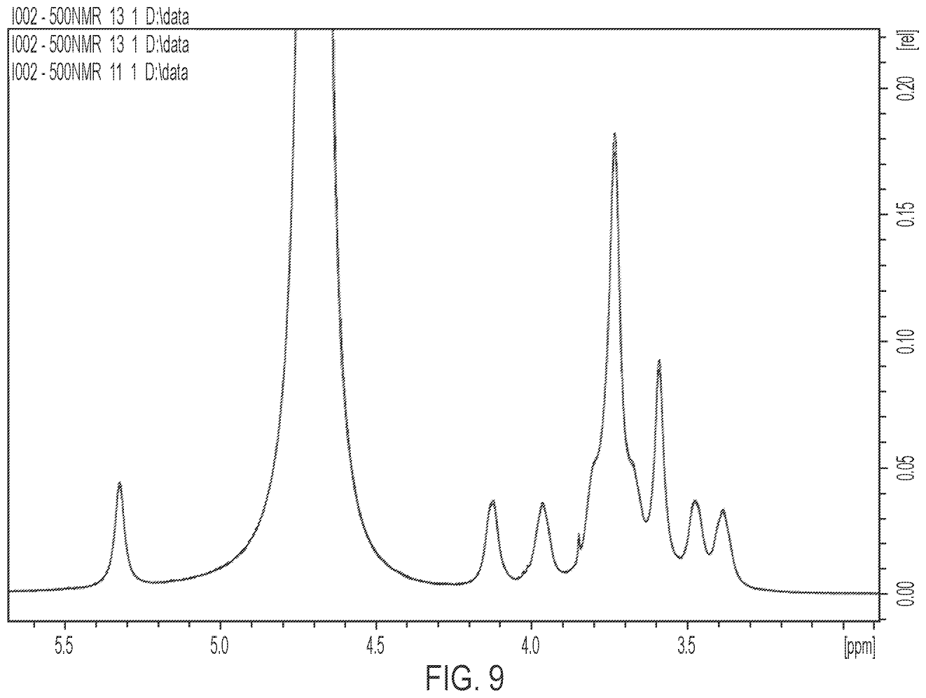

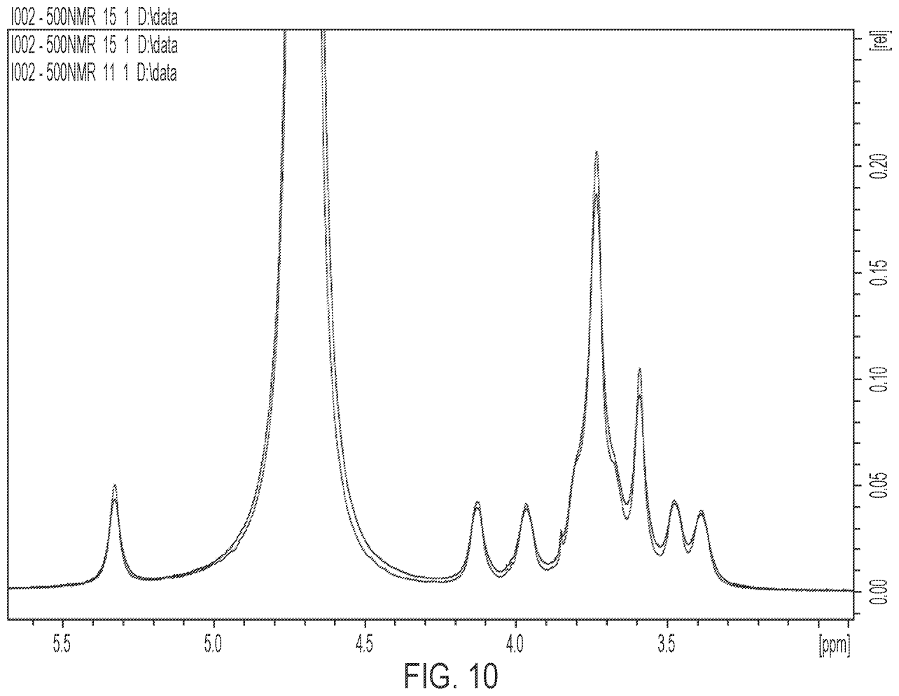

Table 7 and FIG. 7 provide the T1 NMR results for the iron sucrose drug product lots described in Example 5. FIGS. 8-10 compare the ¹H NMR spectra for various lots listed in Table 7 below. Specifically, FIG. 8 compares the ¹H NMR spectra for a comparator product (Venofer 904 (control)) and a tested product (bad iron sucrose Lot 04-17-14 (negative control)), FIG. 9 compares the ¹H NMR spectra for a comparator product (Venofer 9043 (control)) and a tested product (good iron sucrose Lot 09-20-19-B), and FIG. 10 is compares the ¹H NMR spectra for a comparator product (Venofer 9043 (control)) and a tested product (01-27-18-B).

The T1 of Venofer® (Venofer 9030A) using H₂O as the solvent was determined to be 1.191 second at ˜4.7 ppm (see FIG. 7).

TABLE 7
T1 values of Iron sucrose samples at ~4.7 PPM (H₂O)

| Function | Lot# | T1 (second, N = 2-3) |
|---|---|---|
| Positive control | Venofer 9043 | 1.18 |
| | Venofer 9030A | 1.19 |
| | Venofer 8212A | 1.16 |
| Negative control | 04-17-14 | 2.95 |
| Good sample | 09-20-19-B | 1.21 |
| | 09-13-19-A | 1.19 |
| | 10-18-19-B | 1.18 |
| problematic sample | 01-27-18-B | 1.05 |
| | 01-27-18-A | 1.06 |

Table 7 shows that the T1 method can evaluate small and big differences between comparator product and proposed tested iron sucrose samples. T1 values of three comparator product samples at ˜4.7 ppm (Venofer 9043; Venofer9030A; Venofer 8212A) are ˜1.18 seconds which are very similar to T1 values (˜1.19 s) of good tested iron sucrose samples (09-20-19B; 09-13-19A and 10-18-19-B) at same conditions. Negative control (Lot 04-17-2014) is a known bad iron sucrose sample. As expected, it gives much larger T1 values as 2.96 seconds at 4.7 ppm than comparator product samples. In addition, it is already known that tested iron sucrose Lots 01-27-18-A and B has small difference compared to comparator product samples. As expected, T1 values of these 2 lots are ˜10% less than T1 values of the comparator product. Therefore, this T1 method can be used to evaluate small and big differences between the comparator product and proposed tested iron sucrose samples.

FIG. 7 shows the T1 of a sample of Venofer® (Venofer 9030A). The T1 value shown in FIG. 7 was determined by fitting the magnetization curve using the following equation: M=M₀ (1-2e^{-t/T1}). In order to confirm T1 NMR results, ¹H NMR results of sucrose was also performed. FIGS. 8, 9, and 10 show that the ¹H NMR results are highly consistent with T1 NMR result. FIG. 8 shows ¹H NMR differences between comparator product (Venofer 9043) and bad iron sucrose Lot 04-17-14 (negative control). FIG. 9 shows almost same ¹H NMR between comparator product (Venofer 9043) and good iron sucrose Lot 09-20-19-B. FIG. 10 shows small ¹H NMR differences between comparator product (Venofer 9043) and iron sucrose 01-27-18-B.

T1 value of iron sucrose samples were measured at ˜4.7 ppm. ˜4.7 PPM was selected because this peak has highest peak intensity and it has good repeatability. The peak at ˜4.7 ppm is water peak which is from iron sucrose product (see FIG. 7). Without being bound by theory it is thought that the T1 NMR method measures how the structure of the iron sucrose affect its solvent water's T1 relaxation speed. Different iron sucrose's structure such as different core structure or sucrose shell structure could both affect water's relaxation speed.

### VII. Illustrative Embodiments

Provided here are illustrative embodiments of the disclosed technology. These embodiments are illustrative only and do not limit the scope of the present disclosure or of the claims attached.

A. Illustrative Embodiments of Assessing Iron Sucrose Particle Size

Embodiment 1. A method for characterizing iron sucrose comprising the steps of: performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; determining a first set of peak width at half-height (PWHH) having at least twelve PWHHs, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; and analyzing the first and second sets of PWHHs by comparing the first set of PWHH to the second set of PWHH.

Embodiment 2. The method of embodiment 1, wherein the analyzing step further comprises the steps of: determining a set of equivalence evaluation criteria (EEC) based on the second set of PWHH, wherein the first set of EEC comprises at least 12 EECs, wherein each EEC is determined based on EEC Equations 1, 2, 3, and 5, with η=20%, for each PWHH in the second set of PWHH; and determining whether each PWHH in the first set of PWHH meets the respective EEC in the set of EEC.

Embodiment 3. A method for characterizing iron sucrose comprising the steps of: performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; performing ¹³C NMR on a third sample to produce a third ¹³C NMR spectrum, wherein the third sample comprises a plurality of sucrose particles, and the third sample does not include any iron particle; determining a first set of peak width at half-height (PWHH) having at least twelve PWHHs, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; determining a third set of PWHH having at least twelve PWHHs, wherein each PWHH corresponds to a ¹³C peak on the third ¹³C NMR spectrum; determining a first set of RPWHH (“RPWHH”) having at least twelve RPWHHs, wherein each RPWHH is the respective PWHH from the first set of PWHH divided by the corresponding PWHH from the third set of PWHH; determining a second set of RPWHH having at least twelve RPWHHs, wherein each RPWHH is the respective PWHH from the second set of PWHH divided by the corresponding PWHH from the third set of PWHH; and analyzing the first and second sets of RPWHHs by comparing the first set of RPWHH to the second set of RPWHH.

Embodiment 4. The method of embodiment 3, wherein the analyzing step further comprises the steps of: determining a set of equivalence evaluation criteria (EEC) based on the second set of RPWHH, wherein the set of EEC comprises at least 12 EECs, w % herein each EEC is determined based on EEC Equations 1, 2, 3, and 5, with η=20%, for each RPWHH in the second set of RPWHH; and determining whether each RPWHH in the first set of RPWHH meets the respective EEC in the set of EEC.

Embodiment 5. The method of any one of embodiments 1-4, wherein the tested iron sucrose drug product and the comparator product both have an equivalent concentration of about 20 mg/mL of iron.

Embodiment 6. The method of any one of embodiments 1-4, wherein the ¹³C peaks on the first, second, and third ¹³C NMR spectra correspond to the Carbon atoms identified as 1, 2, 3, 4, 5, 6, 1′, 2′, 3′, 4′, 5′, and 6′ in FIG. 1.

Embodiment 7. A method for characterizing iron sucrose comprising the steps of: performing ¹³C NMR on a first set of samples to produce a corresponding first set of ¹³C NMR spectra, wherein the first set of samples comprises at least three (3) different concentrations of iron in a first sample, wherein the first sample comprises a plurality of iron sucrose particles having an iron core particle and a plurality of sucrose particles surrounding the iron core particle, and wherein the first sample is a tested iron sucrose drug product; performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron sucrose particles having an iron core particle a plurality of sucrose particles surrounding the iron core particle, and wherein the second sample is a comparator product for iron sucrose; performing ¹³C NMR on a third sample to produce a third ¹³C NMR spectrum, wherein the third sample comprises a plurality of sucrose particles, and the third sample does not include any iron particle; determining, for each concentration of the first sample, an average value of a first set of peak width at half-height (PWHH), wherein the PWHH is a width at a half-height of the ¹³C peak, wherein the first set of PWHH comprises at least twelve PWHHs, each PWHH corresponding to each ¹³C peak in the respective ¹³C NMR spectrum of the first set of the ¹³C NMR spectra, and wherein the average value is the mean of the at least twelve PWHHs; determining, for each concentration of the second sample, the average value of a second set of PWHH, wherein the second set of PWHH comprises at least twelve PWHHs, each PWHH corresponding to each ¹³C peak in the respective ¹³C NMR spectrum of the second set of the ¹³C NMR spectra; determining the average value of a third set of PWHH, wherein the third set of PWHH comprises at least twelve PWHHs, each PWHH corresponding to each ¹³C peak in the third ¹³C NMR spectrum; determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH; and determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH.

Embodiment 8. The method of embodiment 7, further comprising the step of plotting a graph having the concentration of iron as an X-axis, and the RPWHHs as a Y-axis, using the first and the second sets of RPWHH.

Embodiment 9. The method of embodiment 8, wherein the correlation coefficient is at least 0.98.

Embodiment 10. The method of embodiment 7, wherein the method further comprises the steps of: determining a set of equivalence evaluation criteria (EEC) based on the second set of RPWHH, wherein the set of EEC comprises at least 3 EECs, wherein each is determined based on EEC Equations 1, 2, 3, and 4, with η=20%, for each RPWHH in the second set of RPWHH; and determining whether each RPWHH in the first set of RPWHH meets the respective EEC in the set of EEC.

Embodiment 11. The method of any one of embodiments 8-10, further comprising at least five different concentrations of iron in iron sucrose.

Embodiment 12. The method of embodiment 11, wherein the five different concentrations of iron includes about 0 mg/mL, about 0.1 mg/mL, about 0.4 mg/mL, about 0.8 mg/mL, or about 2 mg/mL.

Embodiment 13. The method of any one of embodiments 8-10, further comprising at least six different concentrations of iron in iron sucrose.

Embodiment 14. The method of embodiment 13, wherein the six different concentrations of iron includes about 0 mg/mL, about 0.1 mg/mL, about 0.4 mg/mL, about 0.8 mg/mL, about 2 mg/mL, and about 3.2 mg/mL.

Embodiment 15. The method of any one of embodiments 8-10, further comprising at least eight different concentrations of iron in iron sucrose.

Embodiment 16. The method of embodiment 15, wherein the eight different concentrations of iron includes about 0 mg/mL, about 0.03 mg/mL, about 0.1 mg/mL, about 0.2 mg/mL, about 0.4 mg/mL, about 0.8 mg/mL, about 2 mg/mL, and about 3.2 mg/mL.

Embodiment 17. The method of any one of embodiments 7-16, wherein the iron is iron (III) hydroxide.

Embodiment 18. A method for characterizing iron sucrose comprising the steps of: applying a reducing agent to one or more first samples, wherein the first sample comprises a plurality of iron sucrose particles having an iron core particle and a plurality of sucrose particles surrounding the iron core particle, wherein the first sample is a tested iron sucrose drug product, and wherein the reducing agent reduces the iron core particle from iron (III) to iron (II); performing ¹H NMR to at least one ¹H in the first sample for an NMR analysis time period, wherein the at least one ¹H is an ¹H associated with the sucrose particle, and during the NMR analysis time period, the reducing agent is reducing iron(III) to iron(II) of the iron core particle of the first sample; applying the reducing agent to one or more second samples, wherein the second sample comprises a plurality of iron sucrose particles having an iron core particle and a plurality of sucrose particles surrounding the iron core particle, wherein the second sample is a comparator product for iron sucrose, wherein the reducing agent reduces the iron core particle from iron (III) to iron (II); performing ¹H NMR to at least one ¹H on the second sample for the NMR analysis time period, wherein the at least one ¹H is the same ¹H associated with the sucrose particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples.

Embodiment 19. The method of embodiment 18, wherein the at least one ¹H associated with the sucrose particle has a chemical shift of about 5.3 parts per million (ppm) to about 5.5 ppm.

Embodiment 20. The method of embodiment 18, wherein the at least one ¹H associated with the sucrose particle has a chemical shift of about 5.4 ppm.

Embodiment 21. The method of any one of embodiments 18-20, wherein the reducing agent is sodium metabisulfite, potassium metabisulfite, (−) ascorbic acid, (+) ascorbic acid, or racemic ascorbic acid.

Embodiment 22. The method of embodiment 21, wherein the reducing agent is sodium metabisulfite.

Embodiment 23. The method of any one of embodiments 18-22, wherein the method further comprises the step of: performing a first log plot of the change in the intensity of the ¹H peak of the at least one ¹H over the NMR analysis time period for the first sample; performing a second log plot of the change in the intensity of the ¹H peak of the at least one ¹H over the NMR analysis time period for the second sample; and wherein the log plots are provided in a log graph having a Y-axis of relative ¹H peak intensity (Log %) and a X-axis of time, wherein the relative ¹H peak intensity (Log %) is calculated based on Log (100*(Observed Peak−Final Peak)/(Initial Peak−Final Peak)).

Embodiment 24. The method of embodiment 23, wherein the Initial Peak is the first measured ¹H peak of the at least one ¹H during an initial NMR analysis time period, the Final Peak is the highest measured ¹H peak of the at least one ¹H during a latter NMR analysis time period, and the Observed Peak is the measured ¹H peak of the least one ¹H at a desired time point within the NMR analysis time period.

Embodiment 25. The method of embodiment 24, wherein the initial NMR analysis time period is from about the 3^{rd} minute to about the 8^{th} minute after ¹H NMR analysis has begun on the respective sample, and the latter NMR analysis time period is from about the 50^{th} minute to about the 100^{th} minute after ¹H NMR analysis has begun on the respective sample.

Embodiment 26. The method of embodiment 25, wherein the Initial Peak is measured at about the 6^{th} minute, the Final Peak is the highest measured ¹H peak between about the 75^{th} minute and about the 90^{th} minute, and the Observed Peak is measured at 2-minute intervals between about the 6^{th} minute through about the 90^{th} minute.

Embodiment 27. The method of embodiment 26, wherein the Final Peak is greater than the Initial Peak, and the Observed Peak is greater than the Initial Peak.

Embodiment 28. The method of any one of embodiments 18-27, wherein the NMR analysis time is at least 60 minutes.

Embodiment 29. The method of any one of embodiments 18-27, wherein the NMR analysis time period is at least 90 minutes.

Embodiment 30. The method of any one of embodiments 23-27, further comprising the steps of: determining a t_{1/2} for the first sample, and determining a t_{1/2} for the second sample, wherein t_{1/2} is determined by (Log 50 minus (the respective y-intercept))/(the respective slope).

Embodiment 31. The method of embodiment 30, wherein the t_{1/2} is an approximate time at which the ¹H peak intensity of the at least one ¹H has increased by about 50 percent during the NMR analysis time period, which is indicative of an approximate 50 percent reduction of the iron(III) to the iron(II) in the iron core particle of the respective sample during the NMR analysis time period.

Embodiment 32. The method of embodiment 31, further comprising the steps of: determining a 2t_{1/2} and a 3t_{1/2} for the first sample, and determining a 2t_{1/2} and a 3t_{1/2} for the second sample, wherein 2t_{1/2} is determined by (Log 25 minus (the respective y-intercept))/(the respective slope), and 3t_{1/2} is determined by (Log 12.5 minus (the respective y-intercept))/(the respective slope).

Embodiment 33. The method of embodiment 32, wherein: the 2t_{1/2} is an approximate time at which the ¹H peak intensity of the at least one ¹H has increased by about 75 percent during the NMR analysis time period, which is indicative of an approximate 75 percent reduction of the iron(III) to the iron(II) in the iron core particle of the respective sample during the NMR analysis time period, and the 3t_{1/2} is an approximate time at which the ¹H peak intensity of the at least one ¹H has increased by about 87.5 percent during the NMR analysis time period, which is indicative of an approximate 87.5 percent reduction of the iron(III) to the iron(II) in the iron core particle of the respective sample during the NMR analysis time period

Embodiment 34. The method of embodiment 32 or 33, further comprising the steps of: determining a set of equivalence evaluation criteria (EEC) based on the second log plot, wherein the set of EEC comprises EEC based on one or more of the t_{1/2}, the 2t_{1/2}, and the 3t_{1/2} from the second log plot, wherein each EEC is determined based on EEC Equations 1, 2, 3, and 4, with η=20%, of the respective parameter of second log plot; and determining whether the corresponding parameter of the first log plot meets the respective EEC in the set of EEC.

Embodiment 35. The method of any one of embodiments 23-26, further comprising: determining a first reduction rate based on the first log plot, and determining a second reduction rate based on the second log plot, wherein the reduction rate is defined as the relative ¹H peak intensity (Log %) divided by a period of time.

Embodiment 36. The method of embodiment 35, further comprising the steps of:

determining a set of equivalence evaluation criteria (EEC) based on the second log plot, wherein the set of EEC comprises EEC based on the second reduction rate, wherein each EEC is determined based on EEC Equations 1, 2, 3, and 4, with η=20%, of the respective parameter of second log plot; and determining whether the corresponding parameter of the first log plot meets the respective EEC in the set of EEC.

Embodiment 37. The method of any one of embodiments 1-36, wherein the plurality of sucrose particles serves as a ligand to the iron core particle.

Embodiment 38. The method of any one of embodiments 1-37, wherein the plurality of sucrose particle is up to about 50 sucrose particles.

Embodiment 39. The method of any one of embodiments 1-38, wherein the plurality of sucrose particles surrounds the iron core particle by forming a shell of sucrose particles around the iron core particle.

The above-referenced embodiments may be used to determine bioequivalence between an iron sucrose drug product and the comparator product. Specifically, when the iron sucrose drug and the comparator product have identical physiological properties as assessed via use of the methods in the embodiments described above, then they are structurally equivalent.

B. Further Illustrative Embodiments

Embodiment 1. A method of characterizing iron carbohydrate comprising the steps of: performing one or more NMR experiments which can measure NMR relaxation values on a first sample to produce a first NMR relaxation spectrum, wherein the first sample comprises a plurality of iron carbohydrate particles having an iron core particle and a plurality of carbohydrate particles surrounding the iron core particle, wherein the first sample is a tested iron carbohydrate drug product; performing one or more NMR experiments which can measure NMR relaxation values on a second sample to produce a second NMR relaxation spectrum, wherein the second sample comprises a plurality of iron carbohydrate particles having an iron core particle and a plurality of carbohydrate particles surrounding the iron core particle, wherein the second sample is a comparator product for the iron carbohydrate; determining relaxation values on a first sample of iron carbohydrate wherein the first sample is a tested iron carbohydrate drug product; determining relaxation values on a second sample of iron carbohydrate wherein the second sample is a comparator product for the iron carbohydrate; and analyzing relaxation values by comparing the first relaxation values to the second relaxation values, wherein when the results of the analysis of relaxation values are the same or substantially the same the tested iron carbohydrate drug product and the comparator product for iron carbohydrate are bioequivalent.

Embodiment 2. The method of embodiment 1, wherein the NMR experiments are T1, T2, ¹H, ¹³C NMR, and combinations thereof.

Embodiment 3. The method of embodiments 1 or 2, wherein the iron carbohydrate is iron dextran, sodium ferric gluconate, iron carboxymaltose, or ferumoxytol.

Embodiment 4. The method of embodiments 1 or 2, wherein the iron carbohydrate is iron sucrose.

Embodiment 5. The method of embodiment 4, wherein the plurality of sucrose particles serves as a ligand to the iron core particle.

Embodiment 6. The method of embodiments 4 or 5, wherein the plurality of sucrose particle is up to about 50 sucrose particles.

Embodiment 7. The method of any one of embodiments 4-6, wherein the plurality of sucrose particles surrounds the iron core particle by forming a shell of sucrose particles around the iron core particle.

Embodiment 8. A method for characterizing iron carbohydrate comprising the steps of: performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product; performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate; determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; and analyzing the first and second sets of PWHHs by comparing the first set of PWHH to the second set of PWHH, wherein when the results of the analysis of the first and second sets of PWHHs are the same or substantially the same the tested iron carbohydrate drug product and the comparator product for iron carbohydrate are structurally equivalent.

Embodiment 9. A method for characterizing iron sucrose comprising the steps of: performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; determining a first set of peak width at half-height (PWHH) having at least twelve PWHHs, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; and analyzing the first and second sets of PWHHs by comparing the first set of PWHH to the second set of PWHH, wherein when the results of the analysis of the first and second sets of PWHHs are the same or substantially the same the tested iron sucrose drug product and the comparator product for iron sucrose are structurally equivalent.

Embodiment 10. The method of embodiments 8 or 9, wherein the analyzing step further comprises the steps of: determining a set of equivalence evaluation criteria (EEC) based on the second set of PWHH, wherein the first set of EEC comprises at least 12 EECs, wherein each EEC is determined based on EEC Equations 1, 2, 3, and 5, with η=20%, for each PWHH in the second set of PWHH; and determining whether each PWHH in the first set of PWHH meets the respective EEC in the set of EEC.

Embodiment 11. A method for characterizing iron carbohydrate comprising the steps of: performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product; performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate; performing ¹³C NMR on a third sample to produce a third ¹³C NMR spectrum, wherein the third sample comprises a plurality of carbohydrate particles, and the third sample does not include any iron particle; determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; determining a third set of PWHH having at least n PWHHs, wherein each PWHH corresponds to a ¹³C peak on the third ¹³C NMR spectrum; determining a first set of relative PWHH (“RPWHH”) having at least n RPWHHs, wherein each RPWHH is the respective PWHH from the first set of PWHH divided by the corresponding PWHH from the third set of PWHH; determining a second set of RPWHH having at least twelve RPWHHs, wherein each RPWHH is the respective PWHH from the second set of PWHH divided by the corresponding PWHH from the third set of PWHH; and analyzing the first and second sets of RPWHHs by comparing the first set of RPWHH to the second set of RPWHH, wherein when the results of the analysis of the first and second sets of RPWHHs are the same or substantially the same the tested iron carbohydrate drug product and the comparator product for the iron carbohydrate are structurally equivalent.

Embodiment 12. A method for characterizing iron sucrose comprising the steps of: performing ¹³C NMR on a first sample to produce a first ¹³C NMR spectrum, wherein the first sample comprises a plurality of iron sucrose particles having an iron core particle and a plurality of sucrose particles surrounding the iron core particle, wherein the first sample is a tested iron sucrose drug product; performing ¹³C NMR on a second sample to produce a second ¹³C NMR spectrum, wherein the second sample comprises a plurality of iron sucrose particles having an iron core particle and a plurality of sucrose particles surrounding the iron core particle, wherein the second sample is a comparator product for iron sucrose; performing ¹³C NMR on a third sample to produce a third ¹³C NMR spectrum, wherein the third sample comprises a plurality of sucrose particles, and the third sample does not include any iron particle; determining a first set of peak width at half-height (PWHH) having at least twelve PWHHs, wherein each PWHH corresponds to a ¹³C peak on the first ¹³C NMR spectrum, and wherein the PWHH is a width at a half-height of the ¹³C peak; determining a second set of PWHH having at least twelve PWHHs, wherein each PWHH corresponds to a ¹³C peak on the second ¹³C NMR spectrum; determining a third set of PWHH having at least twelve PWHHs, wherein each PWHH corresponds to a ¹³C peak on the third ¹³C NMR spectrum; determining a first set of relative PWHH (“RPWHH”) having at least twelve RPWHHs, wherein each RPWHH is the respective PWHH from the first set of PWHH divided by the corresponding PWHH from the third set of PWHH; determining a second set of RPWHH having at least twelve RPWHHs, wherein each RPWHH is the respective PWHH from the second set of PWHH divided by the corresponding PWHH from the third set of PWHH; and analyzing the first and second sets of RPWHHs by comparing the first set of RPWHH to the second set of RPWHH, wherein when the results of the analysis of the first and second sets of RPWHHs are the same or substantially the same the tested iron sucrose drug product and the comparator product for iron sucrose are structurally equivalent.

Embodiment 13. The method of embodiments 11 or 12, wherein the analyzing step further comprises the steps of: determining a set of equivalence evaluation criteria (EEC) based on the second set of RPWHH, wherein the set of EEC comprises at least 12 EECs, wherein each EEC is determined based on EEC Equations 1, 2, 3, and 5, with η=20%, for each RPWHH in the second set of RPWHH; and determining whether each RPWHH in the first set of RPWHH meets the respective EEC in the set of EEC.

Embodiment 14. The method of any one of embodiments 7-13, wherein the tested iron drug product and the comparator product both have an equivalent concentration of about 20 mg/mL of iron.

Embodiment 15. The method of any one of embodiments 9, 10, 12 or 13, wherein the ¹³C peaks on the first, second, and third ¹³C NMR spectra correspond to the Carbon atoms identified as 1, 2, 3, 4, 5, 6, 1′, 2′, 3′, 4′, 5′, and 6′ in FIG. 1.

Embodiment 16. A method for characterizing iron carbohydrate comprising the steps of: performing ¹³C NMR on a first set of samples to produce a corresponding first set of ¹³C NMR spectra, wherein the first set of samples comprises at least three (3) different concentrations of iron in a first sample, wherein the first sample comprises a plurality of iron carbohydrate particles having an iron core particle and a plurality of carbohydrate particles surrounding the iron core particle, and wherein the first sample is a tested iron carbohydrate drug product; performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron carbohydrate particles having an iron core particle a plurality of carbohydrate particles surrounding the iron core particle, and wherein the second sample is a comparator product for the iron carbohydrate; performing ¹³C NMR on a third sample to produce a third ¹³C NMR spectrum, wherein the third sample comprises a plurality of carbohydrate particles, and the third sample does not include any iron particle; determining, for each concentration of the first sample, an average value of a first set of peak width at half-height (PWHH), wherein the PWHH is a width at a half-height of the ¹³C peak, wherein the first set of PWHH comprises at least n PWHHs, wherein n is the number of carbon atoms in the iron carbohydrate, each PWHH corresponding to each ¹³C peak in the respective ¹³C NMR spectrum of the first set of the ¹³C NMR spectra, and wherein the average value is the mean of the at least n PWHHs; determining, for each concentration of the second sample, the average value of a second set of PWHH, wherein the second set of PWHH comprises at least n PWHHs, each PWHH corresponding to each ¹³C peak in the respective ¹³C NMR spectrum of the second set of the ¹³C NMR spectra; determining the average value of a third set of PWHH, wherein the third set of PWHH comprises at least n PWHHs, each PWHH corresponding to each ¹³C peak in the third ¹³C NMR spectrum; determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH; determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH; and comparing the first set of RPWHH to the second set of RPWHH, wherein when the first and second sets of RPWHHs are the same or substantially the same the tested iron carbohydrate drug product and the comparator product for the iron carbohydrate are structurally equivalent.

Embodiment 17. A method for characterizing iron sucrose comprising the steps of: performing ¹³C NMR on a first set of samples to produce a corresponding first set of ¹³C NMR spectra, wherein the first set of samples comprises at least three (3) different concentrations of iron in a first sample, wherein the first sample comprises a plurality of iron sucrose particles having an iron core particle and a plurality of sucrose particles surrounding the iron core particle, and wherein the first sample is a tested iron sucrose drug product; performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron sucrose particles having an iron core particle a plurality of sucrose particles surrounding the iron core particle, and wherein the second sample is a comparator product for iron sucrose; performing ¹³C NMR on a third sample to produce a third ¹³C NMR spectrum, wherein the third sample comprises a plurality of sucrose particles, and the third sample does not include any iron particle; determining, for each concentration of the first sample, an average value of a first set of peak width at half-height (PWHH), wherein the PWHH is a width at a half-height of the ¹³C peak, wherein the first set of PWHH comprises at least twelve PWHHs, each PWHH corresponding to each ¹³C peak in the respective ¹³C NMR spectrum of the first set of the ¹³C NMR spectra, and wherein the average value is the mean of the at least twelve PWHHs; determining, for each concentration of the second sample, the average value of a second set of PWHH, wherein the second set of PWHH comprises at least twelve PWHHs, each PWHH corresponding to each ¹³C peak in the respective ¹³C NMR spectrum of the second set of the ¹³C NMR spectra; determining the average value of a third set of PWHH, wherein the third set of PWHH comprises at least twelve PWHHs, each PWHH corresponding to each ¹³C peak in the third ¹³C NMR spectrum; determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH; determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH; and comparing the first set of RPWHH to the second set of RPWHH, wherein when the first and second sets of RPWHHs are the same or substantially the same the tested iron sucrose drug product and the comparator product for iron sucrose are structurally equivalent.

Embodiment 18. The method of embodiments 16 and 17, further comprising the step of plotting a graph having the concentration of iron as an X-axis, and the RPWHHs as a Y-axis, using the first and the second sets of RPWHH.

Embodiment 19. The method of embodiment 18, wherein the correlation coefficient is at least 0.98.

Embodiment 20. The method of any one of embodiments 16-19, wherein the method further comprises the steps of: determining a set of equivalence evaluation criteria (EEC) based on the second set of RPWHH, wherein the set of EEC comprises at least 3 EECs, wherein each is determined based on EEC Equations 1, 2, 3, and 4, with η=20%, for each RPWHH in the second set of RPWHH; and determining whether each RPWHH in the first set of RPWHH meets the respective EEC in the set of EEC.

Embodiment 21. The method of embodiment 17, further comprising at least five different concentrations of iron in iron sucrose.

Embodiment 22. The method of embodiment 21, wherein the five different concentrations of iron includes about 0 mg/mL, about 0.1 mg/mL, about 0.4 mg/mL, about 0.8 mg/mL, or about 2 mg/mL.

Embodiment 23. The method of embodiment 17, further comprising at least six different concentrations of iron in iron sucrose.

Embodiment 24. The method of embodiment 23, wherein the six different concentrations of iron includes about 0 mg/mL, about 0.1 mg/mL, about 0.4 mg/mL, about 0.8 mg/mL, about 2 mg/mL, and about 3.2 mg/mL.

Embodiment 25. The method of embodiment 17, further comprising at least eight different concentrations of iron in iron sucrose.

Embodiment 26. The method of embodiment 25, wherein the eight different concentrations of iron includes about 0 mg/mL, about 0.03 mg/mL, about 0.1 mg/mL, about 0.2 mg/mL, about 0.4 mg/mL, about 0.8 mg/mL, about 2 mg/mL, and about 3.2 mg/mL.

Embodiment 27. The method of embodiment 17, wherein the iron is iron (III) hydroxide.

Embodiment 28. A method for characterizing iron carbohydrate comprising the steps of: applying a reducing agent to one or more first samples, wherein the first sample comprises a plurality of iron carbohydrate particles having an iron core particle and a plurality of carbohydrate particles surrounding the iron core particle, wherein the first sample is a tested iron carbohydrate drug product, and wherein the reducing agent reduces the iron core particle from iron (III) to iron (II); performing ¹H NMR to at least one ¹H in the first sample for an NMR analysis time period, wherein the at least one ¹H is an ¹H associated with the carbohydrate particle, and during the NMR analysis time period, the reducing agent is reducing iron(III) to iron(II) of the iron core particle of the first sample; applying the reducing agent to one or more second samples, wherein the second sample comprises a plurality of iron carbohydrate particles having an iron core particle and a plurality of carbohydrate particles surrounding the iron core particle, wherein the second sample is a comparator product for the iron carbohydrate, wherein the reducing agent reduces the iron core particle from iron (III) to iron (11); performing ¹H NMR to at least one ¹H on the second sample for the NMR analysis time period, wherein the at least one ¹H is the same ¹H associated with the carbohydrate particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples, wherein the tested iron carbohydrate drug product and the comparator product for iron carbohydrate are structural equivalents when the change in the intensity is the same or substantially the same.

Embodiment 29. A method for characterizing iron sucrose comprising the steps of: applying a reducing agent to one or more first samples, wherein the first sample comprises a plurality of iron sucrose particles having an iron core particle and a plurality of sucrose particles surrounding the iron core particle, wherein the first sample is a tested iron sucrose drug product, and wherein the reducing agent reduces the iron core particle from iron (III) to iron (II); performing ¹H NMR to at least one ¹H in the first sample for an NMR analysis time period, wherein the at least one ¹H is an ¹H associated with the sucrose particle, and during the NMR analysis time period, the reducing agent is reducing iron(III) to iron(II) of the iron core particle of the first sample; applying the reducing agent to one or more second samples, wherein the second sample comprises a plurality of iron sucrose particles having an iron core particle and a plurality of sucrose particles surrounding the iron core particle, wherein the second sample is a comparator product for iron sucrose, wherein the reducing agent reduces the iron core particle from iron (III) to iron (II); performing ¹H NMR to at least one ¹H on the second sample for the NMR analysis time period, wherein the at least one ¹H is the same ¹H associated with the sucrose particle in the second sample, and during the NMR analysis time period, the reducing agent is reducing iron(III) to iron(II) of the iron core particle of the second sample; and determining a change in an intensity of the ¹H peak over the NMR analysis time period for the first and the second samples, wherein the tested iron sucrose drug product and the comparator product for iron sucrose are structural equivalents when the change in the intensity is the same or substantially the same.

Embodiment 30. The method of embodiment 29, wherein the at least one ¹H associated with the sucrose particle has a chemical shift of about 5.3 parts per million (ppm) to about 5.5 ppm.

Embodiment 31. The method of embodiment 29, wherein the at least one ¹H associated with the sucrose particle has a chemical shift of about 5.4 ppm.

Embodiment 32. The method of embodiments 28 or 29, wherein the reducing agent is sodium metabisulfite, potassium metabisulfite, (−) ascorbic acid, (+) ascorbic acid, or racemic ascorbic acid.

Embodiment 33. The method of embodiment 32, wherein the reducing agent is sodium metabisulfite.

Embodiment 34. The method of any one of embodiments 28, 29, 32, or 33, wherein the method further comprises the step of: performing a first log plot of the change in the intensity of the ¹H peak of the at least one ¹H over the NMR analysis time period for the first sample; performing a second log plot of the change in the intensity of the ¹H peak of the at least one ¹H over the NMR analysis time period for the second sample; and wherein the log plots are provided in a log graph having a Y-axis of relative ¹H peak intensity (Log %) and a X-axis of time, wherein the relative ¹H peak intensity (Log %) is calculated based on Log (100*(Observed Peak−Final Peak)/(Initial Peak−Final Peak)).

Embodiment 35. The method of embodiment 34, wherein the Initial Peak is the first measured ¹H peak of the at least one ¹H during an initial NMR analysis time period, the Final Peak is the highest measured ¹H peak of the at least one ¹H during a latter NMR analysis time period, and the Observed Peak is the measured ¹H peak of the least one ¹H at a desired time point within the NMR analysis time period.

Embodiment 36. The method of embodiment 35, wherein the initial NMR analysis time period is from about the 3^{rd} minute to about the 8^{th} minute after ¹H NMR analysis has begun on the respective sample, and the latter NMR analysis time period is from about the 50^{th} minute to about the 100^{th} minute after ¹H NMR analysis has begun on the respective sample.

Embodiment 37. The method of embodiment 36, wherein the Initial Peak is measured at about the 6^{th} minute, the Final Peak is the highest measured ¹H peak between about the 75^{th} minute and about the 90^{th} minute, and the Observed Peak is measured at 2-minute intervals between about the 6^{th} minute through about the 90^{th} minute.

Embodiment 38. The method of embodiment 27, wherein the Final Peak is greater than the Initial Peak, and the Observed Peak is greater than the Initial Peak.

Embodiment 39. The method of any one of embodiments 28-38, wherein the NMR analysis time period is at least 60 minutes.

Embodiment 40. The method of anyone of embodiments 28-39, wherein the NMR analysis time period is at least 90 minutes.

Embodiment 41. The method of embodiment 34, further comprising the steps of: determining a t_{1/2} for the first sample, and determining a t_{1/2} for the second sample, wherein t_{1/2} is determined by (Log 50 minus (the respective y-intercept))/(the respective slope).

Embodiment 42. The method of embodiment 41, wherein the t_{1/2} is an approximate time at which the ¹H peak intensity of the at least one ¹H has increased by about 50 percent during the NMR analysis time period, which is indicative of an approximate 50 percent reduction of the iron(III) to the iron(II) in the iron core particle of the respective sample during the NMR analysis time period.

Embodiment 43. The method of embodiment 42, further comprising the steps of: determining a 2t_{1/2} and a 3t_{1/2} for the first sample, and determining a 2t_{1/2} and a 3t_{1/2} for the second sample, wherein 2t_{1/2} is determined by (Log 25 minus (the respective y-intercept))/(the respective slope), and 3t_{1/2} is determined by (Log 12.5 minus (the respective y-intercept))/(the respective slope).

Embodiment 44. The method of embodiment 43, wherein: the 2t_{1/2} is an approximate time at which the ¹H peak intensity of the at least one ¹H has increased by about 75 percent during the NMR analysis time period, which is indicative of an approximate 75 percent reduction of the iron(III) to the iron(II) in the iron core particle of the respective sample during the NMR analysis time period, and the 3t_{1/2} is an approximate time at which the ¹H peak intensity of the at least one ¹H has increased by about 87.5 percent during the NMR analysis time period, which is indicative of an approximate 87.5 percent reduction of the iron(III) to the iron(II) in the iron core particle of the respective sample during the NMR analysis time period.

Embodiment 45. The method of embodiment 43, further comprising the steps of: determining a set of equivalence evaluation criteria (EEC) based on the second log plot, wherein the set of EEC comprises EEC based on one or more of the t_{1/2}, the 2t_{1/2}, and the 3t_{1/2} from the second log plot, wherein each EEC is determined based on EEC Equations 1, 2, 3, and 4, with η=20%, of the respective parameter of second log plot; and determining whether the corresponding parameter of the first log plot meets the respective EEC in the set of EEC.

Embodiment 46. The method of embodiment 34, further comprising: determining a first reduction rate based on the first log plot, and determining a second reduction rate based on the second log plot, wherein the reduction rate is defined as the relative ¹H peak intensity (Log %) divided by a period of time.

Embodiment 47. The method of embodiment 46, further comprising the steps of: determining a set of equivalence evaluation criteria (EEC) based on the second log plot, wherein the set of EEC comprises EEC based on the second reduction rate, wherein each EEC is determined based on EEC Equations 1, 2, 3, and 4, with η=20%, of the respective parameter of second log plot; and determining whether the corresponding parameter of the first log plot meets the respective EEC in the set of EEC.

Embodiment 48. A method for characterizing iron sucrose via T1 NMR comprising the steps of: performing T1 NMR and determining T1 value on a first sample, wherein the first sample comprises a plurality of iron sucrose particles having an iron core particle and a plurality of sucrose particles surrounding the iron core particle, wherein the first sample is a tested iron sucrose drug product; performing T1 NMR and determine T1 value on a second sample, wherein the second sample comprises a plurality of iron sucrose particles having an iron core particle and a plurality of sucrose particles surrounding the iron core particle, wherein the second sample is a comparator product for the iron sucrose; and analyzing the first and second T1 values by comparing the first sample's T1 to the second sample's T1, wherein when the results of the analysis of the first and second T1 are the same or substantially the same the tested iron sucrose drug product and the comparator product for the iron sucrose are structurally equivalent.

Embodiment 49. A method for characterizing iron carbohydrate via T1 NMR comprising the steps of: performing T1 NMR and determining T1 value on a first sample, wherein the first sample comprises a plurality of iron carbohydrate particles having an iron core particle and a plurality of carbohydrate particles surrounding the iron core particle, wherein the first sample is a tested iron carbohydrate drug product; performing T1 NMR and determine T1 value on a second sample, wherein the second sample comprises a plurality of iron carbohydrate particles having an iron core particle and a plurality of carbohydrate particles surrounding the iron core particle, wherein the second sample is a comparator product for the iron carbohydrate; and analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

Embodiment 50. The method of any one of embodiments 9, 12, 17, 29, or 48 wherein the plurality of sucrose particles serves as a ligand to the iron core particle.

Embodiment 50. The method of any one of embodiments 9, 12, 17, 29, or 48, wherein the plurality of sucrose particle is up to about 50 sucrose particles.

Embodiment 52. The method of any one of embodiments 9, 12, 17, 29, or 48, wherein the plurality of sucrose particles surrounds the iron core particle by forming a shell of sucrose particles around the iron core particle.

Embodiment 53. The method of any one of embodiments 8, 11, 16, 28, or 49, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

Embodiment 54. A method for characterizing iron sucrose comprising the steps of: performing T1 NMR and ¹H NMR experiments which measure T1 NMR and ¹H NMR relaxation values on a first sample to produce a first NMR relaxation spectrum, wherein the first sample comprises a plurality of iron carbohydrate particles having an iron core particle and a plurality of sucrose particles surrounding the iron core particle, wherein the first sample is a tested iron carbohydrate drug product; performing T1 NMR and ¹H NMR experiments which can measure T1 NMR and ¹H NMR relaxation values on a second sample to produce a second NMR relaxation spectrum, wherein the second sample comprises a plurality of iron sucrose particles having an iron core particle and a plurality of carbohydrate particles surrounding the iron core particle, wherein the second sample is a comparator product for the iron carbohydrate; determining relaxation values on a first sample of iron sucrose wherein the first sample is the tested carbohydrate drug product; determining relaxation values on a second sample of iron sucrose wherein the second sample is the comparator product for the iron carbohydrate, and analyzing relaxation values by comparing the first relaxation values to the second relaxation values, wherein when the results of the analysis of relaxation values are the same or substantially the same the tested iron carbohydrate drug product and the compactor product for iron sucrose are bioequivalent.

Embodiment 55. The method of embodiment 54, wherein the plurality of sucrose particles serves as a ligand to the iron core particle.

Embodiment 56. The method of embodiments 54 or 55, wherein the plurality of sucrose particle is up to about 50 sucrose particles.

Embodiment 57. The method of any one of embodiments 54-56, wherein the plurality of sucrose particles surrounds the iron core particle by forming a shell of sucrose particles around the iron core particle.

Embodiment 58. A nuclear magnetic resonance spectrograph configured to perform the methods of any one of embodiments 1-57.

Embodiment 59. A computer program on a non-transitory computer readable medium and having code adapted to be executed by a computer to perform the methods of any one of embodiments 1-57.

While the invention has been described and illustrated herein by references to various specific materials, procedures, and examples, it is understood that the invention is not restricted to the particular combinations of material and procedures selected for that purpose. Numerous variations of such details can be implied as will be appreciated by those skilled in the art. It is intended that the specification and examples be considered as exemplary, only, with the true scope and spirit of the invention being indicated by the following claims. All references, patents, and patent applications referred to in this application are herein incorporated by reference in their entirety.

1. A method of characterizing iron carbohydrate comprising the steps of:
performing one or more NMR experiments which can measure NMR relaxation values on a first sample to produce a first NMR relaxation spectrum, wherein the first sample comprises a plurality of iron carbohydrate particles having an iron core particle and a plurality of carbohydrate particles surrounding the iron core particle, wherein the first sample is a tested iron carbohydrate drug product;
performing one or more NMR experiments which can measure NMR relaxation values on a second sample to produce a second NMR relaxation spectrum, wherein the second sample comprises a plurality of iron carbohydrate particles having an iron core particle and a plurality of carbohydrate particles surrounding the iron core particle, wherein the second sample is a comparator product for the iron carbohydrate;
determining relaxation values on a first sample of iron carbohydrate wherein the first sample is a tested iron carbohydrate drug product;
determining relaxation values on a second sample of iron carbohydrate wherein the second sample is a comparator product for the iron carbohydrate; and
analyzing relaxation values by comparing the first relaxation values to the second relaxation values, wherein when the results of the analysis of relaxation values are the same or substantially the same the tested iron carbohydrate drug product and the comparator product for iron carbohydrate are bioequivalent, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

2. The method of claim 1, wherein the NMR experiments are T1, T2, ¹H, ¹³C NMR, and combinations thereof.

3. (canceled)

4. (canceled)

5. The method of claim 1, wherein the plurality of sucrose particles: serves as a ligand to the iron core particle; is up to about 50 sucrose particles; and/or surrounds the iron core particle by forming a shell of sucrose particles around the iron core particle.

6. (canceled)

7. (canceled)

8. A method for characterizing iron carbohydrate comprising the steps of:
performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product;
performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate;
determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak;
determining a second set of PWHH having at least twelve PWHHs, wherein each PWHH corresponds to a ¹³C peak on the second ¹³C NMR spectrum; and
analyzing the first and second sets of PWHHs by comparing the first set of PWHH to the second set of PWHH, wherein when the results of the analysis of the first and second sets of PWHHs are the same or substantially the same the tested iron carbohydrate drug product and the comparator product for iron carbohydrate are structurally equivalent, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

9. The method of claim 8, wherein the iron carbohydrate is iron sucrose.

10. The method of claim 8, wherein the analyzing step further comprises the steps of:
determining a set of equivalence evaluation criteria (EEC) based on the second set of PWHH, wherein the first set of EEC comprises at least 12 EECs, wherein each EEC is determined based on EEC Equations 1, 2, 3, and 5, with η=20%, for each PWHH in the second set of PWHH; and
determining whether each PWHH in the first set of PWHH meets the respective EEC in the set of EEC.

11. A method for characterizing iron carbohydrate comprising the steps of:
performing ¹³C NMR on a first sample to produce a first ¹³C NMR spectrum, wherein the first sample comprises a plurality of iron carbohydrate particles having an iron core particle and a plurality of carbohydrate particles surrounding the iron core particle, wherein the first sample is a tested iron carbohydrate drug product;
performing ¹³C NMR on a second sample to produce a second ¹³C NMR spectrum, wherein the second sample comprises a plurality of iron carbohydrate particles having an iron core particle and a plurality of carbohydrate particles surrounding the iron core particle, wherein the second sample is a comparator product for the iron carbohydrate;
performing ¹³C NMR on a third sample to produce a third ¹³C NMR spectrum, wherein the third sample comprises a plurality of carbohydrate particles, and the third sample does not include any iron particle;
determining a first set of peak width at half-height (PWHH) having at least n PWHHs, wherein n is the number of carbon atoms in the iron carbohydrate, wherein each PWHH corresponds to a ¹³C peak on the first ¹³C NMR spectrum, and wherein the PWHH is a width at a half-height of the ¹³C peak;
determining a second set of PWHH having at least twelve PWHHs, wherein each PWHH corresponds to a ¹³C peak on the second ¹³C NMR spectrum;
determining a third set of PWHH having at least n PWHHs, wherein each PWHH corresponds to a ¹³C peak on the third ¹³C NMR spectrum;
determining a first set of relative PWHH (“RPWHH”) having at least n RPWHHs, wherein each RPWHH is the respective PWHH from the first set of PWHH divided by the corresponding PWHH from the third set of PWHH;
determining a second set of RPWHH having at least twelve RPWHHs, wherein each RPWHH is the respective PWHH from the second set of PWHH divided by the corresponding PWHH from the third set of PWHH; and
analyzing the first and second sets of RPWHHs by comparing the first set of RPWHH to the second set of RPWHH, wherein when the results of the analysis of the first and second sets of RPWHHs are the same or substantially the same the tested iron carbohydrate drug product and the comparator product for the iron carbohydrate are structurally equivalent, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

12. The method of claim 11, wherein the iron carbohydrate is iron sucrose.

13. The method of claim 11, wherein the analyzing step further comprises the steps of:
determining a set of equivalence evaluation criteria (EEC) based on the second set of RPWHH, wherein the set of EEC comprises at least 12 EECs, wherein each EEC is determined based on EEC Equations 1, 2, 3, and 5, with η=20%, for each RPWHH in the second set of RPWHH; and
determining whether each RPWHH in the first set of RPWHH meets the respective EEC in the set of EEC.

14. (canceled)

15. (canceled)

16. A method for characterizing iron carbohydrate comprising the steps of:
performing ¹³C NMR on a first set of samples to produce a corresponding first set of ¹³C NMR spectra, wherein the first set of samples comprises at least three (3) different concentrations of iron in a first sample, wherein the first sample comprises a plurality of iron carbohydrate particles having an iron core particle and a plurality of carbohydrate particles surrounding the iron core particle, and wherein the first sample is a tested iron carbohydrate drug product;
performing ¹³C NMR on a second set of samples to produce a corresponding second set of ¹³C NMR spectra, wherein the second set of samples comprises at least three different concentrations of iron in a second sample, wherein the at least three different concentrations of the second sample has the same concentrations as the at least three different concentrations of the first sample, wherein the second sample comprises a plurality of iron carbohydrate particles having an iron core particle a plurality of carbohydrate particles surrounding the iron core particle, and wherein the second sample is a comparator product for the iron carbohydrate;
performing ¹³C NMR on a third sample to produce a third ¹³C NMR spectrum, wherein the third sample comprises a plurality of carbohydrate particles, and the third sample does not include any iron particle;
determining, for each concentration of the first sample, an average value of a first set of peak width at half-height (PWHH), wherein the PWHH is a width at a half-height of the ¹³C peak, wherein the first set of PWHH comprises at least n PWHHs, wherein n is the number of carbon atoms in the iron carbohydrate, each PWHH corresponding to each ¹³C peak in the respective ¹³C NMR spectrum of the first set of the ¹³C NMR spectra, and wherein the average value is the mean of the at least n PWHHs;
determining, for each concentration of the second sample, the average value of a second set of PWHH, wherein the second set of PWHH comprises at least n PWHHs, each PWHH corresponding to each ¹³C peak in the respective ¹³C NMR spectrum of the second set of the ¹³C NMR spectra;
determining the average value of a third set of PWHH, wherein the third set of PWHH comprises at least n PWHHs, each PWHH corresponding to each ¹³C peak in the third ¹³C NMR spectrum;
determining a first set of relative PWHH (“RPWHH”), wherein the first set of RPWHH comprises at least three RPWHHS, wherein each PWHH corresponds to the at least three different concentrations, wherein each RPWHH is the average value of a first set of PWHH divided by the average value of the third set of PWHH;
determining a second set of RPWHH, wherein the second set of RPWHH comprises at least three RPWHHS, wherein each PWHH corresponds to the at least three different concentrations, wherein each RPWHH is the average value of a second set of PWHH divided by the average value of the third set of PWHH; and
comparing the first set of RPWHH to the second set of RPWHH, wherein when the first and second sets of RPWHHs are the same or substantially the same the tested iron carbohydrate drug product and the comparator product for the iron carbohydrate are structurally equivalent, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

17. The method of claim 16, wherein the iron carbohydrate is iron sucrose and optionally wherein the iron is iron (III) hydroxide.

18. The method of claim 16, further comprising the step of plotting graph having the concentration of iron as an X-axis, and the RPWHHs as a Y-axis, using in the first the second sets of RPWHH.

19. (canceled)

20. The method of claim 16, wherein the method further comprises the steps of:
determining a set of equivalence evaluation criteria (EEC) based on the second set of RPWHH, wherein the set of EEC comprises at least 3 EECs, wherein each is determined based on EEC Equations 1, 2, 3, and 4, with η=20%, for each RPWHH in the second set of RPWHH; and
determining whether each RPWHH in the first set of RPWHH meets the respective EEC in the set of EEC.

21. (canceled)

22. (canceled)

23. (canceled)

24. (canceled)

25. (canceled)

26. (canceled)

27. (canceled)

28. A method for characterizing iron carbohydrate comprising the steps of:
applying a reducing agent to one or more first samples, wherein the first sample comprises a plurality of iron carbohydrate particles having an iron core particle and a plurality of carbohydrate particles surrounding the iron core particle, wherein the first sample is a tested iron carbohydrate drug product, and wherein the reducing agent reduces the iron core particle from iron (III) to iron (II);
performing ¹H NMR to at least one ¹H in the first sample for an NMR analysis time period, wherein the at least one ¹H is an ¹H associated with the carbohydrate particle, and during the NMR analysis time period, the reducing agent is reducing iron(III) to iron(II) of the iron core particle of the first sample;
applying the reducing agent to one or more second samples, wherein the second sample comprises a plurality of iron carbohydrate particles having an iron core particle and a plurality of carbohydrate particles surrounding the iron core particle, wherein the second sample is a comparator product for the iron carbohydrate, wherein the reducing agent reduces the iron core particle from iron (III) to iron (II);
performing ¹H NMR to at least one ¹H on the second sample for the NMR analysis time period, wherein the at least one ¹H is the same ¹H associated with the carbohydrate particle in the second sample, and during the NMR analysis time period, the reducing agent is reducing iron(III) to iron(II) of the iron core particle of the second sample; and
determining a change in an intensity of the ¹H peak over the NMR analysis time period for the first and the second samples, wherein the tested iron carbohydrate drug product and the comparator product for iron carbohydrate are structural equivalents when the change in the intensity is the same or substantially the same, wherein the iron carbohydrate drug product is an iron sucrose drug product, a high molecule weight iron dextran drug product, a low molecular weight iron dextran drug product, a sodium ferric gluconate drug product, an iron carboxymaltose drug product, or a ferumoxytol drug product.

29. The method of claim 28, wherein the iron carbohydrate is iron sucrose.

30. The method of claim 29, wherein the at least one ¹H associated with the sucrose particle has a chemical shift of about 5.3 parts per million (ppm) to about 5.5 ppm or about 5.4 ppm.

31. (canceled)

32. The method of claim 28, wherein the reducing agent is sodium metabisulfite, potassium metabisulfite, (−) ascorbic acid, (+) ascorbic acid, or racemic ascorbic acid.

33. (canceled)

34. The method of claim 28, wherein the method further comprises the step of:
performing a first log plot of the change in the intensity of the ¹H peak of the at least one ¹H over the NMR analysis time period for the first sample;
performing a second log plot of the change in the intensity of the ¹H peak of the at least one ¹H over the NMR analysis time period for the second sample; and
wherein the log plots are provided in a log graph having a Y-axis of relative ¹H peak intensity (Log %) and a X-axis of time, wherein the relative ¹H peak intensity (Log %) is calculated based on Log (100*(Observed Peak−Final Peak)/(Initial Peak−Final Peak)).

35. The method of claim 34, wherein the Initial Peak is the first measured ¹H peak of the at least one ¹H during an initial NMR analysis time period, the Final Peak is the highest measured ¹H peak of the at least one ¹H during a latter NMR analysis time period, and the Observed Peak is the measured ¹H peak of the least one ¹H at a desired time point within the NMR analysis time period.

36. The method of claim 35, wherein the initial NMR analysis time period is from about the 3^{rd} minute to about the 8^{th} minute after ¹H NMR analysis has begun on the respective sample, and the latter NMR analysis time period is from about the 50^{th} minute to about the 100^{th} minute after ¹H NMR analysis has begun on the respective sample, and optionally wherein the Initial Peak is measured at about the 6^{th} minute, the Final Peak is the highest measured ¹H peak between about the 75^{th} minute and about the 90^{th} minute, and the Observed Peak is measured at 2-minute intervals between about the 6^{th} minute through about the 90^{th} minute.

37. (canceled)

38. (canceled)

39. (canceled)

40. (canceled)

41. The method of claim 34, further comprising the steps of:
determining a t_{1/2} for the first sample, and
determining a t_{1/2} for the second sample,
wherein t_{1/2} is determined by (Log 50 minus (the respective y-intercept))/(the respective slope), optionally wherein the t_{1/2} is an approximate time at which the ¹H peak intensity of the at least one ¹H has increased by about 50 percent during the NMR analysis time period, which is indicative of an approximate 50 percent reduction of the iron(III) to the iron(II) in the iron core particle of the respective sample during the NMR analysis time period.

42. (canceled)

43. The method of claim 41, further comprising the steps of:
determining a 2t_{1/2} and a 3t_{1/2} for the first sample, and
determining a 2t_{1/2} and a 3t_{1/2} for the second sample,
wherein 2t_{1/2} is determined by (Log 25 minus (the respective y-intercept))/(the respective slope), and 3t_{1/2} is determined by (Log 12.5 minus (the respective y-intercept))/(the respective slope).

44. The method of claim 43, wherein:
the 2t_{1/2} is an approximate time at which the ¹H peak intensity of the at least one ¹H has increased by about 75 percent during the NMR analysis time period, which is indicative of an approximate 75 percent reduction of the iron(III) to the iron(II) in the iron core particle of the respective sample during the NMR analysis time period, and
the 3t_{1/2} is an approximate time at which the ¹H peak intensity of the at least one ¹H has increased by about 87.5 percent during the NMR analysis time period, which is indicative of an approximate 87.5 percent reduction of the iron(III) to the iron(II) in the iron core particle of the respective sample during the NMR analysis time period, optionally wherein the method further comprises the steps of: determining a set of equivalence evaluation criteria (EEC) based on the second log plot, wherein the set of EEC comprises EEC based on one or more of the t_{1/2}, the 2t_{1/2}, and the 3t_{1/2} from the second log plot, wherein each EEC is determined based on EEC Equations 1, 2, 3, and 4, with η=20%, of the respective parameter of second log plot; and determining whether the corresponding parameter of the first log plot meets the respective EEC in the set of EEC.

45. (canceled)

46. The method of claim 34, further comprising:
determining a first reduction rate based on the first log plot, and
determining a second reduction rate based on the second log plot,
wherein the reduction rate is defined as the relative ¹H peak intensity (Log %) divided by a period of time, optionally wherein the method further comprises the steps of:
determining a set of equivalence evaluation criteria (EEC) based on the second log plot, wherein the set of EEC comprises EEC based on the second reduction rate, wherein each EEC is determined based on EEC Equations 1, 2, 3, and 4, with η=20%, of the respective parameter of second log plot; and
determining whether the corresponding parameter of the first log plot meets the respective EEC in the set of EEC.

47. (canceled)

48. A method for characterizing iron sucrose via T1 NMR comprising the steps of:
performing T1 NMR and determining T1 value on a first sample, wherein the first sample comprises a plurality of iron sucrose particles having an iron core particle and a plurality of sucrose particles surrounding the iron core particle, wherein the first sample is a tested iron sucrose drug product;
performing T1 NMR and determine T1 value on a second sample, wherein the second sample comprises a plurality of iron sucrose particles having an iron core particle and a plurality of sucrose particles surrounding the iron core particle, wherein the second sample is a comparator product for the iron sucrose; and
analyzing the first and second T1 values by comparing the first sample's T1 to the second sample's T1, wherein when the results of the analysis of the first and second T1 are the same or substantially the same the tested iron sucrose drug product and the comparator product for the iron sucrose are structurally equivalent.

49. A method for characterizing iron carbohydrate via T1 NMR comprising the steps of:
performing T1 NMR and determining T1 value on a first sample, wherein the first sample comprises a plurality of iron carbohydrate particles having an iron core particle and a plurality of carbohydrate particles surrounding the iron core particle, wherein the first sample is a tested iron carbohydrate drug product;
performing T1 NMR and determine T1 value on a second sample, wherein the second sample comprises a plurality of iron carbohydrate particles having an iron core particle and a plurality of carbohydrate particles surrounding the iron core particle, wherein the second sample is a comparator product for the iron carbohydrate; and
analyzing the first and second T1 values by comparing the first sample's T1 to the second sample's T1, wherein when the results of the analysis of the first and second T1 are the same or substantially the same the tested iron carbohydrate drug product and the comparator product for the iron carbohydrate are structurally equivalent.

50. The method of claim 9, wherein the plurality of sucrose particles serves as a ligand to the iron core particle.

51. The method of claim 12, wherein the plurality of sucrose particle is up to about 50 sucrose particles.

52. The method of claim 12, wherein the plurality of sucrose particles surrounds the iron core particle by forming a shell of sucrose particles around the iron core particle.

53. (canceled)

54. A method for characterizing iron sucrose comprising the steps of:
performing T1 NMR and ¹H NMR experiments which measure T1 NMR and ¹H NMR relaxation values on a first sample to produce a first NMR relaxation spectrum, wherein the first sample comprises a plurality of iron carbohydrate particles having an iron core particle and a plurality of sucrose particles surrounding the iron core particle, wherein the first sample is a tested iron carbohydrate drug product;
performing T1 NMR and ¹H NMR experiments which can measure T1 NMR and ¹H NMR relaxation values on a second sample to produce a second NMR relaxation spectrum, wherein the second sample comprises a plurality of iron sucrose particles having an iron core particle and a plurality of carbohydrate particles surrounding the iron core particle, wherein the second sample is a comparator product for the iron carbohydrate;
determining relaxation values on a first sample of iron sucrose wherein the first sample is the tested carbohydrate drug product;
determining relaxation values on a second sample of iron sucrose wherein the second sample is the comparator product for the iron carbohydrate; and
analyzing relaxation values by comparing the first relaxation values to the second relaxation values, wherein when the results of the analysis of relaxation values are the same or substantially the same the tested iron carbohydrate drug product and the compactor product for iron sucrose are bioequivalent.

55. The method of claim 54, wherein the plurality of sucrose particles serves as a ligand to the iron core particle.

56. The method of claim 54, wherein the plurality of sucrose particle is up to about 50 sucrose particles.

57. The method of claim 54, wherein the plurality of sucrose particles surrounds the iron core particle by forming a shell of sucrose particles around the iron core particle.

58. (canceled)

59. (canceled)
